(19) United States
(12) Patent Application Publication
(10) Pub. No.: US 2006/0220763 A1
(43) Pub. Date: Oct. 5, 2006

(54) Acoustic mirror type thin film bulk acoustic resonator, and filter, duplexer and communication apparatus comprising the same

(76) Inventors: Tomohiro Iwasaki, Toyonaka (JP); Hiroshi Nakatsuka, Katano (JP); Keiji Onishi, Settsu (JP); Hiroyuki Nakamura, Katano (JP)

Correspondence Address: WENDEROTH, LIND & PONACK L.L.P., 2033 K. STREET, NW, SUITE 800, WASHINGTON, DC, 20006, US

(21) Appl. No.: 10/552,582

(22) PCT Filed: Mar. 31, 2005
(86) PCT No.: PCT/JP05/06810

§ 371 Date: Oct. 12, 2005

(51) Int. Cl. H03H 9/00

(52) U.S. Cl. 333/133; 333/191

(57) ABSTRACT

A thin film bulk acoustic resonator (507b) comprises a substrate (101b), an acoustic mirror layer (508b) provided on the substrate (101b), including a plurality of impedance layers (502b, 503b) alternatively having a high acoustic impedance and a low acoustic impedance, and a piezoelectric thin film vibrator (509b) provided on the acoustic mirror layer (508b), including a lower electrode (504b), a piezoelectric thin film (105b) and an upper electrode (506b). The sum of a thickness of the lower electrode (504b) and a thickness of the upper electrode (506b) is 5% or more and 60% or less of a whole thickness of the piezoelectric thin film vibrator (509b), and the thickness of the lower electrode (504b) is larger than the thickness of the upper electrode (506b).

### TECHNICAL FIELD

The present invention relates to a resonator for use in a high frequency circuit of a wireless apparatus or the like. More particularly, the present invention relates to a thin film bulk acoustic resonator having an acoustic mirror structure, and a filter, a duplexer and a communication apparatus which each comprise the same.

### BACKGROUND ART

With the recent advances in downsizing and cost cutting of wireless communication apparatuses, there is an increasing demand for miniaturization and integration of a filter mounted thereon. To meet the demand, a dielectric filter, a multilayer filter, a bulk acoustic filter and the like have been developed. The bulk acoustic filter includes a thin film bulk acoustic resonator which utilizes a piezoelectric thin film.

The thin film bulk acoustic resonator has a structure such that a piezoelectric thin film is interposed between two electrodes. When a voltage is applied between the electrodes of the thin film bulk acoustic resonator, a piezoelectric effect which is induced in response to the voltage application causes mechanical piezoelectric vibration (elastic vibration).

The thin film bulk acoustic resonator includes an acoustic mirror type thin film bulk acoustic resonator with a mirror structure which utilizes an acoustic mirror effect. FIG. 28 is a cross-sectional view of a conventional acoustic mirror type thin film bulk acoustic resonator. In FIG. 28, an acoustic mirror type thin film bulk acoustic resonator 907a comprises a substrate 901a, acoustic mirror layers 902a and 903a, a lower electrode 904a, a piezoelectric thin film 905a, and an upper electrode 906a.

The acoustic mirror layers 902a and 903a are formed on the substrate 901a. The acoustic mirror layers 902a and 903a are composed of a combination of a plurality of materials having different acoustic impedances. A piezoelectric thin film vibrator 909a, which is composed of the lower electrode 904a, the upper electrode 906a and the piezoelectric thin film 905a interposed therebetween, is provided on the acoustic mirror layers 902a and 903a.

In a general acoustic mirror layer, high acoustic impedance materials (the acoustic mirror layers 902a) and low acoustic impedance materials (the acoustic mirror layers 903a) are alternately disposed so that an impedance mismatch surface is formed on an interface between each layer. Each acoustic mirror layer has a thickness which is equal to one fourth of an acoustic wavelength calculated from a resonant frequency in free space of the piezoelectric thin film vibrator 909a. The size of one fourth of the acoustic wavelength is calculated by:
λ(wavelength)/4=v/(4·fr) or v/(4·fa)
where v represents the speed of sound transmitting through each of the acoustic mirror layers 902a and 903a, fr represents the resonant frequency of the piezoelectric thin film vibrator 909a, and fa represents the antiresonant frequency of the piezoelectric thin film vibrator 909a.

Thus, a vibration wave (sonic wave) induced in the piezoelectric thin film vibrator 909a is transmitted through each acoustic mirror layer and is reflected from the interface (impedance mismatch surface) of each layer. The reflected vibration waves are combined at a resonant frequency (antiresonant frequency) and in the same phase, thereby improving resonance characteristics. The resonance bandwidth of the resonance characteristics can be increased by increasing an impedance mismatch ratio, i.e., an impedance ratio of the high impedance layer to the low impedance layer. The acoustic impedance of the substrate with respect to the piezoelectric thin film vibrator can be reduced by increasing the number of acoustic mirror layers, thereby improving the resonance characteristics. This has been well known. However, conventionally, a thickness (C) of the lower electrode 904a is not strictly defined.

Conventional techniques are disclosed in, for example:

Patent Publication 1: Japanese Patent Laid-Open Publication No. 9-199978;

Patent Publication 2: Japanese Patent Laid-Open Publication No. 6-295181; and

Patent Publication 3: Japanese Patent Laid-Open Publication No. 2002-41052.

FIG. 29 is a diagram showing a vibration distribution in the acoustic mirror type thin film bulk acoustic resonator 907a of FIG. 28. When the thicknesses of the upper electrode 906a and the lower electrode 904a are considerably small compared to the thickness of the piezoelectric thin film 905a, an acoustic wavelength is λ/2 in the piezoelectric thin film vibrator 909a as in FIG. 29. In this case, by setting the thickness of each mirror layer to be one fourth of an acoustic wavelength at the resonant frequency (or antiresonant frequency) of the piezoelectric thin film vibrator, reflected vibration waves are combined in the same phase, thereby making it possible to improve resonance characteristics.

However, in actual devices, the thickness of the electrode is often significant with respect to the thickness of the piezoelectric thin film. Therefore, the vibration distribution in the piezoelectric thin film vibrator deviates from λ/2. Therefore, when the thickness of each mirror layer is simply set to be one fourth of the acoustic wavelength at the resonant frequency (or the antiresonant frequency), reflection does not take place exactly at λ/4. As a result, the frequency of reflected vibration is shifted, so that resonance characteristics, particularly the bandwidth of resonance (Δf), is deteriorated.

### DISCLOSURE OF THE INVENTION

Therefore, an object of the present invention is to provide an acoustic mirror type thin film bulk acoustic resonator having excellent resonance characteristics.

To achieve the object, the present invention has the following features. The present invention provides an acoustic mirror type thin film bulk acoustic resonator comprising a substrate, an acoustic mirror layer provided on the substrate, including a plurality of impedance layers alternately having a high acoustic impedance and a low acoustic impedance, and a piezoelectric thin film vibrator provided on the acoustic mirror layer, including a lower electrode, a piezoelectric thin film and an upper electrode. The sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

According to the present invention, the thickness of the lower electrode is larger than the thickness of the upper electrode, and therefore, a resonance bandwidth can be broadened as compared to when the thickness of the lower electrode is equal to the thickness of the upper electrode. By broadening the resonance bandwidth, it is possible to prevent a deterioration in resonance characteristics due to variations in the thickness.

Preferably, the plurality of impedance layers may include a plurality of low acoustic impedance layers and a plurality of high acoustic impedance layers which are alternately disposed, and an uppermost one of the low acoustic impedance layers which contacts the lower electrode, may have a thickness of one fourth of an acoustic wavelength defined from a resonant frequency in free space of the piezoelectric thin film vibrator. Thereby, the resonance bandwidth can be further broadened.

Preferably, each of the plurality of low acoustic impedance layers may have a thickness of one fourth of the acoustic wavelength defined from the resonant frequency in free space of the piezoelectric thin film vibrator. Thereby, the resonance bandwidth can be further broadened.

Preferably, the plurality of impedance layers may include a plurality of low acoustic impedance layers and a plurality of high acoustic impedance layers which are alternately disposed, and an uppermost one of the low acoustic impedance layers which contacts the lower electrode, may have a thickness of less than one fourth of an acoustic wavelength defined from a resonant frequency in free space of the piezoelectric thin film vibrator. Thereby, the resonance bandwidth can be further broadened.

Preferably, each of the plurality of low acoustic impedance layers may have a thickness of less than one fourth of the acoustic wavelength defined from the resonant frequency in free space of the piezoelectric thin film vibrator. Thereby, the resonance bandwidth can be further broadened.

Preferably, the plurality of impedance layers may include a plurality of low acoustic impedance layers and a plurality of high acoustic impedance layers which are alternately disposed, and an uppermost one of the low acoustic impedance layers which contacts the lower electrode, may have a thickness of more than one fourth of an acoustic wavelength defined from a resonant frequency in free space of the piezoelectric thin film vibrator. Thereby, the resonance bandwidth can be further broadened.

Preferably, each of the plurality of low acoustic impedance layers may have a thickness of more than one fourth of the acoustic wavelength defined from the resonant frequency in free space of the piezoelectric thin film vibrator. Thereby, the resonance bandwidth can be further broadened.

Preferably, the plurality of impedance layers may include a plurality of low acoustic impedance layers and a plurality of high acoustic impedance layers which are alternately disposed, and at least an uppermost one of the plurality of low acoustic impedance layer, may have a thickness different from one fourth of an acoustic wavelength defined from a resonant frequency in free space of the piezoelectric thin film vibrator, and an uppermost one of the high acoustic impedance layers may have a thickness different from one fourth of the acoustic wavelength defined from the resonant frequency in free space of the piezoelectric thin film vibrator. Thereby, the resonance bandwidth can be further broadened.

Preferably, each of the plurality of high acoustic impedance layers may have a thickness different from one fourth of the acoustic wavelength defined from the resonant frequency in free space of the piezoelectric thin film vibrator. Thereby, the resonance bandwidth can be further broadened.

The present invention also provides a filter comprising two or more thin film bulk acoustic resonators which are connected in a ladder form, wherein at least one of the thin film bulk acoustic resonators comprises a substrate, an acoustic mirror layer provided on the substrate, including a plurality of impedance layers alternately having a high acoustic impedance and a low acoustic impedance, and a piezoelectric thin film vibrator provided on the acoustic mirror layer, including a lower electrode, a piezoelectric thin film and an upper electrode, wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

The present invention also provides a duplexer comprising a transmission filter and a reception filter, wherein at least one of the transmission filter and the reception filter comprises two or more thin film bulk acoustic resonators which are connected in a ladder form, and at least one of the thin film bulk acoustic resonators comprises a substrate, an acoustic mirror layer provided on the substrate, including a plurality of impedance layers alternately having a high acoustic impedance and a low acoustic impedance, and a piezoelectric thin film vibrator provided on the acoustic mirror layer, including a lower electrode, a piezoelectric thin film and an upper electrode, wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

The present invention also provides a communication apparatus comprising at least thin film one bulk acoustic resonator, wherein the at least thin film one bulk acoustic resonators comprises a substrate, an acoustic mirror layer provided on the substrate, including a plurality of impedance layers alternately having a high acoustic impedance and a low acoustic impedance, and a piezoelectric thin film vibrator provided on the acoustic mirror layer, including a lower electrode, a piezoelectric thin film and an upper electrode, wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

According to the present invention, by causing the thickness of the lower electrode to be larger than the thickness of the upper electrode, it is possible to provide an acoustic mirror type thin film piezoelectric resonator in which a resonance bandwidth can be broadened, and a filter, a duplexer and a communication apparatus comprising the same. Also, by broadening the resonance bandwidth, it is possible to provide an acoustic mirror type thin film piezoelectric resonator in which a deterioration in resonance characteristics due to variations in the thickness of the low acoustic impedance layer can be prevented, and a filter, a duplexer and a communication apparatus comprising the same.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of an acoustic mirror type thin film bulk acoustic resonator according to a first embodiment of the present invention,

FIG. 2 is a graph showing a change in resonance band when a thickness of a low acoustic impedance layer 103b is changed while fixing the other values,

FIG. 3 is a diagram for explaining how a most preferable thickness of the low acoustic impedance layer 103b varies depending on conditions of a piezoelectric thin film vibrator 109b,

FIG. 4 is a cross-sectional view of an acoustic mirror type thin film bulk acoustic resonator according to a second embodiment of the present invention,

FIG. 5 is a graph showing a change in resonance band when a thickness of a high acoustic impedance layer 202b is changed while fixing the other values,

FIG. 6 is a cross-sectional view of an acoustic mirror type thin film bulk acoustic resonator according to a third embodiment of the present invention,

FIG. 7 is a graph showing a change in resonance band when a thickness of a high acoustic impedance layer 302b and a thickness of a low acoustic impedance layer 303b are simultaneously changed at the same rate,

FIG. 8 is a graph for explaining that an effect of the present invention is obtained to a further extent with an increase in thicknesses of upper and lower electrodes,

FIG. 9 is a graph showing for explaining that the effect of the present invention is obtained to a further extent with an increase in the ratio of an acoustic impedance of a high acoustic impedance layer to an acoustic impedance of a low acoustic impedance layer,

FIG. 10 is a cross-sectional view of an acoustic mirror type thin film bulk acoustic resonator according to a fourth embodiment of the present invention,

FIG. 11 is a graph showing a change in resonance band when a thickness of an uppermost low acoustic impedance layer 403b is changed while fixing the other values,

FIG. 12 is a cross-sectional view of an acoustic mirror type thin film bulk acoustic resonator according to a fifth embodiment of the present invention,

FIG. 13 is a graph showing a band ratio where an electrode ratio is 10%,

FIG. 14 is a graph showing a band ratio where the electrode ratio is 14%,

FIG. 15 is a graph showing a band ratio where the electrode ratio is 20%,

FIG. 16 is a graph showing a band ratio where the electrode ratio is 30%,

FIG. 17 is a graph showing a band ratio where the electrode ratio is 40%,

FIG. 18 is a graph showing a band ratio where the electrode ratio is 50%,

FIG. 19 is a graph showing a band ratio where the electrode ratio is 60%,

FIG. 20 is a graph showing a band ratio where the electrode ratio is 70%,

FIG. 21 is a graph showing a band ratio where the electrode ratio is 80%,

FIG. 22 is a graph showing an optimum value of an upper/lower ratio,

FIG. 23 is a graph showing a band ratio when the electrode ratio is 5%,

FIGS. 24A and 24B are diagrams showing exemplary filters comprising acoustic mirror type thin film bulk acoustic resonators of the present invention,

FIG. 25 is a diagram showing a first exemplary apparatus comprising an acoustic mirror type thin film bulk acoustic resonator of the present invention,

FIG. 26 is a diagram showing a second exemplary apparatus comprising an acoustic mirror type thin film bulk acoustic resonator of the present invention,

FIG. 27 is a diagram showing a third exemplary apparatus comprising an acoustic resonator of the present invention,

FIG. 28 is a cross-sectional view of a conventional acoustic mirror type thin film bulk acoustic resonator, and

FIG. 29 is a diagram showing an ideal vibration distribution in an acoustic mirror type thin film bulk acoustic resonator 907a of FIG. 28.

### BEST MODE FOR CARRYING OUT THE INVENTION

Hereinafter, embodiments of the present invention will be described with reference to the accompanying drawings.

### First Embodiment

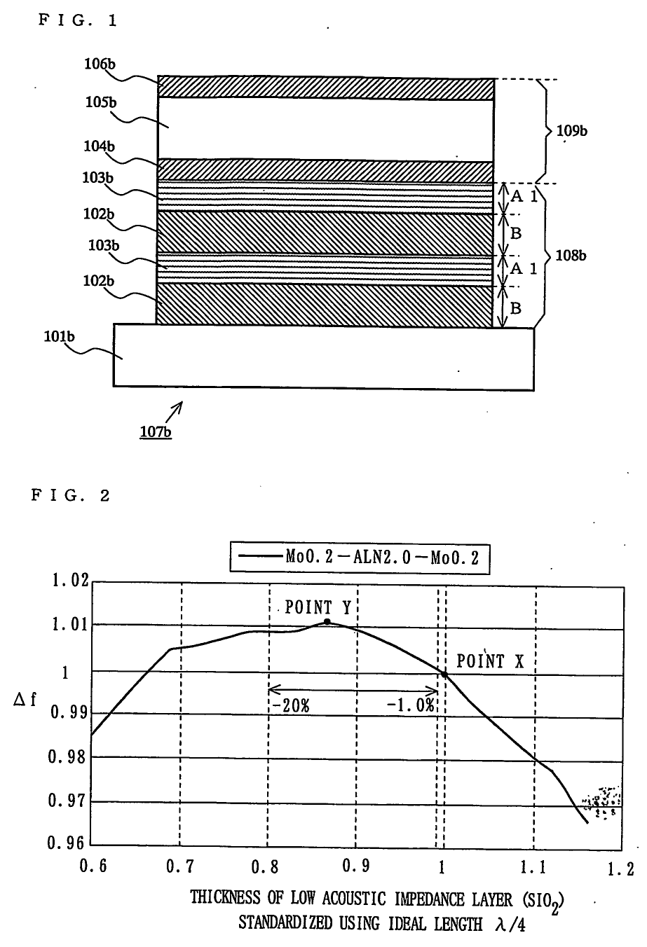

FIG. 1 is a cross-sectional view of an acoustic mirror type thin film bulk acoustic resonator according to a first embodiment of the present invention. In FIG. 1, the acoustic mirror type thin film bulk acoustic resonator 107b comprises a substrate 101b, high acoustic impedance layers 102b, low acoustic impedance layers 103b, a lower electrode 104b, a piezoelectric thin film 105b, and an upper electrode 106b.

The number of the high acoustic impedance layers 102b is two in FIG. 1, or alternatively, may be one, or three or more. Also, the number of the low acoustic impedance layers 103b is two in FIG. 1, or alternatively, may be one, or three or more. Note that an uppermost one of the low acoustic impedance layers 103b is formed immediately below the lower electrode 104b. The low acoustic impedance layers 103b and the high acoustic impedance layers 102b are alternately formed.

An acoustic mirror layer 108b, which is composed of the high acoustic impedance layers 102b and the low acoustic impedance layers 103b, is provided on the substrate 101b. On the acoustic mirror layer 108b, a piezoelectric thin film vibrator 109b, which is composed of the lower electrode 104b, the piezoelectric thin film 105b and the upper electrode 106b, is provided.

The high acoustic impedance layer 102b is made of a high acoustic impedance material, such as tungsten (W), molybdenum (Mo) or the like. A thickness (B) of the high acoustic impedance layer 102b is equal to one fourth of an acoustic wavelength which is calculated from a resonant frequency (antiresonant frequency) in free space of the piezoelectric thin film vibrator 109b.

The low acoustic impedance layer 103b is made of a low acoustic impedance material, such as silicon dioxide (SiO₂) or the like. A thickness (A1) of the low acoustic impedance layer 103b is equal to a thickness which maximizes a bandwidth of resonance characteristics. The present inventors found that the thickness (Al) of the low acoustic impedance layer 103b which maximizes the bandwidth of the resonance characteristics is smaller than the size of one fourth of the acoustic wavelength calculated from the resonant frequency (antiresonant frequency) in free space of the piezoelectric thin film vibrator 109b.

The lower electrode 104b is made of, for example, molybdenum (Mo), aluminum (Al), platinum (Pt), gold (Au) or the like.

The piezoelectric thin film 105b is made of, for example, aluminum nitride (AlN), zinc oxide (ZnO), or the like.

The upper electrode 106b is made of, for example, molybdenum (Mo), aluminum (Al), platinum (Pt), gold (Au), or the like.

In a production process of the acoustic mirror type thin film bulk acoustic resonator 107b, the thickness of each acoustic mirror layer varies in one chip due to an influence of surface roughness of the substrate 101b, the low acoustic impedance layer 103b and the high acoustic impedance layer 102b.

In addition, film forming conditions vary depending on a position on a wafer, resulting in variations in chip. Due to an influence of the chip variation, the thickness of each acoustic mirror layer varies among a plurality of chips.

The magnitude of the variation is about 1% at maximum with respect to the thickness.

Therefore, the thickness (Al) of the low acoustic impedance layer 103b is preferably lower by 1% or more than one fourth of the acoustic wavelength calculated from the resonant frequency in free space of the piezoelectric thin film vibrator 109b, taking its variations into consideration.

FIG. 2 is a graph showing a change in resonance band when the thickness of the low acoustic impedance layer 103b is changed while fixing the other values. Here, it is assumed that the lower electrode 104b is made of molybdenum (Mo) and has a thickness of 0.2 μm, the piezoelectric thin film 105b is made of aluminum nitride and has a thickness of 2.0 μm, and the upper electrode 106b is made of molybdenum (Mo) and has a thickness of 0.2 μm.

In FIG. 2, the horizontal axis represents a value obtained by standardizing the thickness of the low acoustic impedance layer 103b using the size of one fourth of the acoustic wavelength λ calculated from the resonant frequency in free space of the piezoelectric thin film vibrator 109b (hereinafter referred to as “ideal length λ/4”). The vertical axis represents a value obtained by standardizing a change in a resonance bandwidth using a bandwidth (Δf) which is obtained when the thickness of the low acoustic impedance layer 103b is equal to the ideal length λ/4. On the horizontal axis and the vertical axis, a value of 1 is a value which is obtained when the thickness of the low acoustic impedance layer 103b is equal to the ideal length λ/4.

As can be seen from FIG. 2, the thickness of the low acoustic impedance layer 103b which maximizes the resonance bandwidth is obtained at a thickness point Y which is smaller than a thickness point X corresponding to the ideal length λ/4. Therefore, the thickness of the low acoustic impedance layer 103b is preferably smaller than the size of one fourth of the acoustic wavelength which is calculated from the resonant frequency (antiresonant frequency) in free space of the piezoelectric thin film vibrator 109b.

For example, the degree of a change in resonance bandwidth at the point X is compared with the degree of a change in resonance bandwidth at the point Y, assuming that there is, for example, a variation of ±1% in thickness. In this case, it will be found that the change degree is smaller at the point Y than at the point X. Therefore, when the thickness at the point Y is determined to be the thickness (A′) of the low acoustic impedance layer 103b, a change in resonance band due to a variation in thickness can be further reduced. Thereby, an influence of the thickness variation can be minimized.

Also as can be seen from FIG. 2, when the thickness of the low acoustic impedance layer 103b is more than 0.8 times the length λ/4, i.e., more than [the ideal length λ/4 minus 20.0%], a change in resonance band due to the thickness variation can be reduced. Therefore, taking the thickness variation into consideration, the thickness of the low acoustic impedance layer 103b is preferably in the range of [the ideal length λ/4 minus 20.0%] to [the ideal length λ/4 minus 1.0%).

Within the range of [the ideal length λ/4 minus 20.0%) to [the ideal length λ/4 minus 1.0%), the most preferable thickness of the low acoustic impedance layer 103b varies depending on conditions of the piezoelectric thin film vibrator 109b.

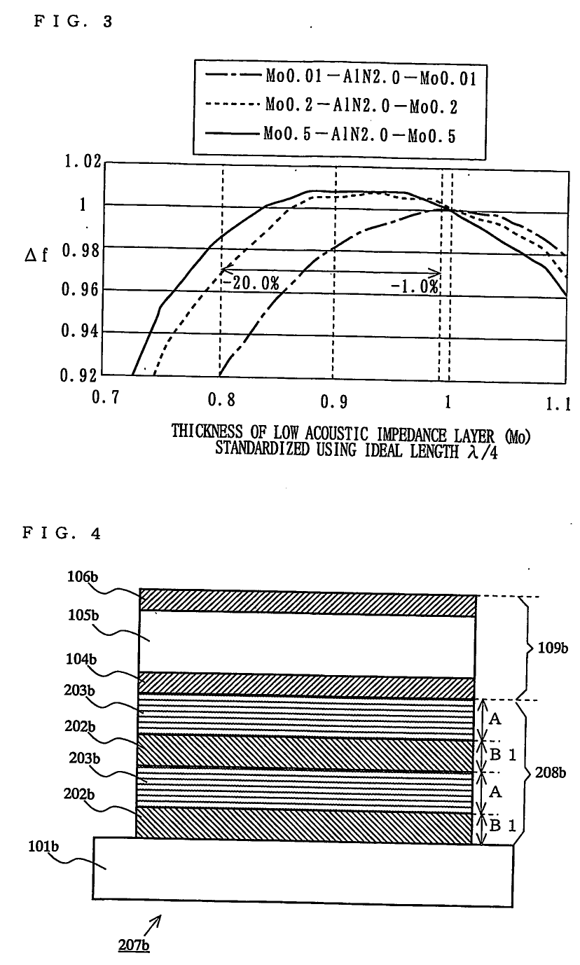

FIG. 3 is a diagram for explaining how the most preferable thickness of the low acoustic impedance layer 103b varies depending on the conditions of the piezoelectric thin film vibrator 109b.

In FIG. 3, it is assumed that the piezoelectric thin film 105b is made of aluminum nitride (AlN), the lower electrode 104b and the upper electrode 106b are made of molybdenum (Mo), the thickness of the piezoelectric thin film 105b is fixed to 2.0 μm, and the thicknesses of the lower electrode 104b and the upper electrode 106b are set to be 0.01 μm, 0.2 μm or 0.5 μm. In this case, resonance bands Δf obtained by changing the thickness of the low acoustic impedance layer 103b are compared.

Typically, when an electrode material is deposited by a process technique, such as sputtering or the like, the thinnest thickness of an electrode is considered to be about 0.01 μm. In the case of this value, when the thickness of the low acoustic impedance layer 103b is [the ideal length λ/4 minus about 1%], the resonance band Δf becomes larger than when the thickness is the ideal length λ/4.

Therefore, as can be seen from FIG. 3, the most preferable thickness of the low acoustic impedance layer 103b is included in the range of [the ideal length λ/4 minus 20.0%] to [the ideal length λ/4 minus 1.0%], no matter that the piezoelectric thin film vibrator is constructed with any settings.

Next, a description will be given of why the thickness of the low acoustic impedance layer 103b is preferably smaller than the ideal length λ/4.

In the thin film bulk acoustic resonator which utilizes the acoustic mirror, the piezoelectric thin film 105b generally resonates with a frequency corresponding to a wavelength of λ/2. However, the thicknesses of the lower electrode 104b and the upper electrode 106b are significantly large with respect to the thickness of the piezoelectric thin film 105b. The thicknesses of the upper and lower electrodes have an influence on a vibration distribution.

Since the piezoelectric thin film vibrator 109b is deposited on the acoustic mirror layer 108b, the mass load thereof is applied to the low acoustic impedance layer 103b and the high acoustic impedance layer 102b. The mass load has an influence on a vibration distribution in the acoustic mirror layer.

According to the above-described two factors, the vibration distribution in each acoustic mirror layer substantially deviates from the ideal λ/4 vibration distribution. Therefore, it will be understood that an optimum thickness of the low acoustic impedance layer 103b is smaller than the ideal length λ/4.

Thus, according to the first embodiment, by setting the thickness of the low acoustic impedance layer of the acoustic mirror layers in the acoustic mirror type thin film bulk acoustic resonator to be smaller than the size of one fourth of the acoustic wavelength calculated from the resonant frequency (antiresonant frequency) in free space of the piezoelectric thin film vibrator, the resonance bandwidth can be broadened. By broadening the resonance bandwidth, it is possible to prevent a degradation in resonance characteristics due to variations in the thickness of the low acoustic impedance layer.

Although the thickness of each low acoustic impedance layer is smaller than the ideal length λ/4 in the first embodiment, a similar effect can be obtained if at least one low acoustic impedance layer has a thickness which is lower than the ideal length λ/4.

Also in the first embodiment, a low acoustic impedance layer is provided immediately below the lower electrode, and therebelow, high acoustic impedance layer(s) and low acoustic impedance layer(s) are alternately provided. Alternatively, a high acoustic impedance layer may be provided immediately below the lower electrode, and therebelow, low acoustic impedance layer(s) and high acoustic impedance layer(s) may be alternately provided.

### Second Embodiment

FIG. 4 is a cross-sectional view of an acoustic mirror type thin film bulk acoustic resonator according to a second embodiment of the present invention. In FIG. 4, the acoustic mirror type thin film bulk acoustic resonator 207b comprises a substrate 101b, high acoustic impedance layers 202b, low acoustic impedance layers 203b, a lower electrode 104b, a piezoelectric thin film 105b, and an upper electrode 106b. In FIG. 4, the same parts as those of the first embodiment are referenced with the same reference numerals and will not be explained.

The number of the high acoustic impedance layers 202b is two in FIG. 4, or alternatively, may be one, or three or more. Also, the number of the low acoustic impedance layers 203b is two in FIG. 4, or alternatively, may be one, or three or more. Note that an uppermost one of the low acoustic impedance layers 203b is formed immediately below the lower electrode 104b. The low acoustic impedance layers 203b and the high acoustic impedance layers 202b are alternately formed in the same number.

An acoustic mirror layer 208b, which is composed of the high acoustic impedance layers 202b and the low acoustic impedance layers 203b, is provided on the substrate 101b. On the acoustic mirror layer 208b, a piezoelectric thin film vibrator 109b, which is composed of the lower electrode 104b, the piezoelectric thin film 105b and the upper electrode 106b, is provided.

The high acoustic impedance layer 202b is made of a high acoustic impedance material, such as tungsten (W), molybdenum (Mo) or the like. A thickness (B1) of the high acoustic impedance layer 202b is equal to a thickness which maximizes a bandwidth of resonance characteristics. The present inventors found that the thickness (B1) of the high acoustic impedance layer 202b which maximizes the bandwidth of the resonance characteristics is smaller than the size of one fourth of an acoustic wavelength calculated from a resonant frequency (antiresonant frequency) in free space of the piezoelectric thin film vibrator 109b.

The low acoustic impedance layer 203b is made of a low acoustic impedance material, such as silicon dioxide (SiO₂) or the like. A thickness (A) of the low acoustic impedance layer 203b is equal to the size of one fourth of the acoustic wavelength calculated from the resonant frequency (antiresonant frequency) in free space of the piezoelectric thin film vibrator 109b.

In a production process of the acoustic mirror type thin film bulk acoustic resonator 207b, the thickness of each acoustic mirror layer varies in one chip due to an influence of surface roughness of the substrate 101b, the low acoustic impedance layer 203b, and the high acoustic impedance layer 202b.

In addition, film forming conditions vary depending on a position on a wafer, resulting in variations in chip. Due to an influence of the chip variation, the thickness of each acoustic mirror layer varies among a plurality of chips.

The magnitude of the variation is about 1% at maximum with respect to the thickness.

Therefore, the thickness (B1) of the high acoustic impedance layer 202b is preferably lower by 1% or more than one fourth of the acoustic wavelength calculated from the resonant frequency in free space of the piezoelectric thin film vibrator 109b, taking its variations into consideration.

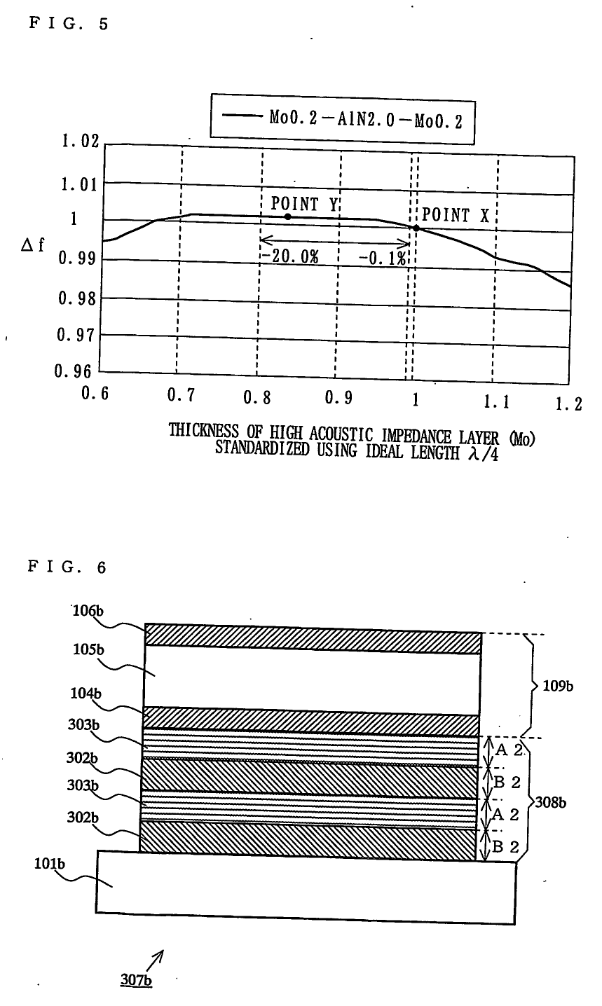

FIG. 5 is a graph showing a change in resonance band when the thickness of the high acoustic impedance layer 202b is changed while fixing the other values. Here, it is assumed that the lower electrode 104b is made of molybdenum (Mo) and has a thickness of 0.2 μm, the piezoelectric thin film 105b is made of aluminum nitride and has a thickness of 2.0 μm, and the upper electrode 106b is made of molybdenum (Mo) and has a thickness of 0.2 μm.

In FIG. 5, the horizontal axis represents a value obtained by standardizing the thickness of the high acoustic impedance layer 202b using the ideal length λ/4. The vertical axis represents a value obtained by standardizing a change in a resonance bandwidth using a bandwidth (Δf) which is obtained when the thickness of the high acoustic impedance layer 202b is equal to the ideal length λ/4. On the horizontal axis and the vertical axis, a value of 1 is a value which is obtained when the thickness of the high acoustic impedance layer 202b is equal to the ideal length λ/4.

As can be seen from FIG. 5, the thickness of the high acoustic impedance layer 202b which maximizes the resonance bandwidth is obtained at a thickness point Y which is smaller than a thickness point X corresponding to the ideal length λ/4. Therefore, the thickness of the high acoustic impedance layer 202b is preferably smaller than the size of one fourth of the acoustic wavelength which is calculated from the resonant frequency (antiresonant frequency) in free space of the piezoelectric thin film vibrator 109b.

For example, the degree of a change in resonance bandwidth at the point X is compared with the degree of a change in resonance bandwidth at the point Y, assuming that there is, for example, a variation of ±1% in thickness. In this case, it will be found that the change degree is smaller at the point Y than at the point X. Therefore, when the thickness at the point Y is determined to be the thickness (B1) of the high acoustic impedance layer 202b, a change in resonance band due to a variation in thickness can be further reduced. Thereby, an influence of the thickness variation can be minimized.

Also as can be seen from FIG. 5, when the thickness of the high acoustic impedance layer 202b is more than 0.8 times the length λ/4, i.e., more than (the ideal length λ/4 minus 20.0%], a change in resonance band due to the thickness variation can be reduced. Therefore, taking the thickness variation into consideration, the thickness of the high acoustic impedance layer 202b is preferably in the range of [the ideal length λ/4 minus 20.0%].to [the ideal length λ/4 minus 1.0%].

The principle of why the thickness of the high acoustic impedance layer 202b is preferably smaller than the size of one fourth of the acoustic wavelength which is calculated from the resonant frequency (antiresonant frequency) in free space of the piezoelectric thin film vibrator 109b, is similar to that of the first embodiment.

Thus, according to the second embodiment, by setting the thickness of the high acoustic impedance layer of the acoustic mirror layers in the acoustic mirror type thin film bulk acoustic resonator to be smaller than the size of one fourth of an acoustic wavelength calculated from the resonant frequency (antiresonant frequency) in free space of the piezoelectric thin film vibrator, the resonance bandwidth can be broadened. By broadening the resonance bandwidth, it is possible to prevent a degradation in resonance characteristics due to variations in the thickness of the high acoustic impedance layer.

Although the thickness of each high acoustic impedance layer is smaller than the ideal length λ/4 in the second embodiment, a similar effect can be obtained if at least one high acoustic impedance layer has a thickness which is lower than the ideal length λ/4.

Also in the second embodiment, a low acoustic impedance layer is provided immediately below the lower electrode, and therebelow, high acoustic impedance layer(s) and low acoustic impedance layer(s) are alternately provided. Alternatively, a high acoustic impedance layer may be provided immediately below the lower electrode, and therebelow, low acoustic impedance layer(s) and high acoustic impedance layer(s) may be alternately provided.

### Third Embodiment

FIG. 6 is a cross-sectional view of an acoustic mirror type thin film bulk acoustic resonator according to a third embodiment of the present invention. In FIG. 6, the acoustic mirror type thin film bulk acoustic resonator 307b comprises a substrate 101b, high acoustic impedance layers 302b, low acoustic impedance layers 303b, a lower electrode 104b, a piezoelectric thin film 105b, and an upper electrode 106b. In FIG. 6, the same parts as those of the first embodiment are referenced with the same reference numerals and will not be explained.

The number of the high acoustic impedance layers 302b is two in FIG. 6, or alternatively, may be one, or three or more. Also, the number of the low acoustic impedance layers 303b is two in FIG. 6, or alternatively, may be one, or three or more. Note that an uppermost one of the low acoustic impedance layers 303b is formed immediately below the lower electrode 104b. The low acoustic impedance layers 303b and the high acoustic impedance layers 302b are alternately formed in the same number.

An acoustic mirror layer 308b, which is composed of the high acoustic impedance layers 302b and the low acoustic impedance layers 303b, is provided on the substrate 101b. On the acoustic mirror layer 308b, a piezoelectric thin film vibrator 109b, which is composed of the lower electrode 104b, the piezoelectric thin film 105b and the upper electrode 106b, is provided.

The high acoustic impedance layer 302b is made of a high acoustic impedance material, such as tungsten (W), molybdenum (Mo) or the like. A thickness (B2) of the high acoustic impedance layer 302b is smaller than the size of one fourth of an acoustic wavelength calculated from a resonant frequency (antiresonant frequency) in free space of the piezoelectric thin film vibrator 109b.

The low acoustic impedance layer 303b is made of a low acoustic impedance material, such as silicon dioxide (SiO₂) or the like. A thickness (A2) of the low acoustic impedance layer 303b is smaller than the size of one fourth of the acoustic wavelength calculated from the resonant frequency (antiresonant frequency) in free space of the piezoelectric thin film vibrator 109b.

In a production process of the acoustic mirror type thin film bulk acoustic resonator 307b, the thickness of each acoustic mirror layer varies in one chip due to an influence of surface roughness of the substrate 101b, the low acoustic impedance layer 303b, and the high acoustic impedance layer 302b.

In addition, film forming conditions vary depending on a position on a wafer, resulting in variations in chip. Due to an influence of the chip variation, the thickness of each acoustic mirror layer varies among a plurality of chips.

The magnitude of the variation is about 1% at maximum with respect to the thickness.

Therefore, the thickness (A2) of the low acoustic impedance layer 303b and the thickness (B2) of the high acoustic impedance layer 302b are each preferably lower by 1% or more than one fourth of the acoustic wavelength calculated from the resonant frequency in free space of the piezoelectric thin film vibrator 109b, taking their variations into consideration.

FIG. 7 is a graph showing a change in resonance band when the thickness of the high acoustic impedance layer 302b and the thickness of the low acoustic impedance layer 303b are simultaneously changed at the same rate. Here, it is assumed that the lower electrode 104b is made of molybdenum (Mo) and has a thickness of 0.2 n, the piezoelectric thin film 105b is made of aluminum nitride and has a thickness of 2.0 μm, and the upper electrode 106b is made of molybdenum (Mo) and has a thickness of 0.2 μm.

In FIG. 7, the horizontal axis represents a value obtained by standardizing the thicknesses of the high acoustic impedance layer 302b and the low acoustic impedance layer 303b using the ideal length λ/4. The vertical axis represents a value obtained by standardizing a change in a resonance bandwidth using a bandwidth (Δf) which is obtained when the thicknesses of the high acoustic impedance layer 302b and the low acoustic impedance layer 303b are each equal to the ideal length λ/4. On the horizontal axis and the vertical axis, a value of 1 is a value which is obtained when the thicknesses of the high acoustic impedance layer 302b and the low acoustic impedance layer 303b are each equal to the ideal length λ/4.

As can be seen from FIG. 7, the thicknesses of the high acoustic impedance layer 302b and the low acoustic impedance layer 303b which maximize the resonance bandwidth is obtained at a thickness point Y which is smaller than a thickness point X corresponding to the ideal length λ/4. Therefore, the thicknesses of the high acoustic impedance layer 302b and the low acoustic impedance layer 303b are each preferably smaller than the size of one fourth of the acoustic wavelength which is calculated from the resonant frequency (antiresonant frequency) in free space of the piezoelectric thin film vibrator 109b.

For example, the degree of a change in resonance bandwidth at the point X is compared with the degree of a change in resonance bandwidth at the point Y, assuming that there is, for example, a variation of ±1% in thickness. In this case, it will be found that the change degree is smaller at the point Y than at the point X. Therefore, when the thickness at the point Y is determined to be the thicknesses (A2, B2) of the high acoustic impedance layer 302b and the low acoustic impedance layer 303b, a change in resonance band due to a variation in thickness can be further reduced. Thereby, an influence of the thickness variation can be minimized.

Also as can be seen from FIG. 7, the optimum thicknesses of the high acoustic impedance layer 302b and the low acoustic impedance layer 303b are each preferably in the range of [the ideal length λ/4 minus 20.0%] to [the ideal length λ/4 minus 1.0%].

The principle of why the thicknesses of the high acoustic impedance layer 302b and the low acoustic impedance layer 303b are each preferably smaller than the size of one fourth of the acoustic wavelength which is calculated from the resonant frequency (antiresonant frequency) in free space of the piezoelectric thin film vibrator 109b, is similar to that of the first embodiment.

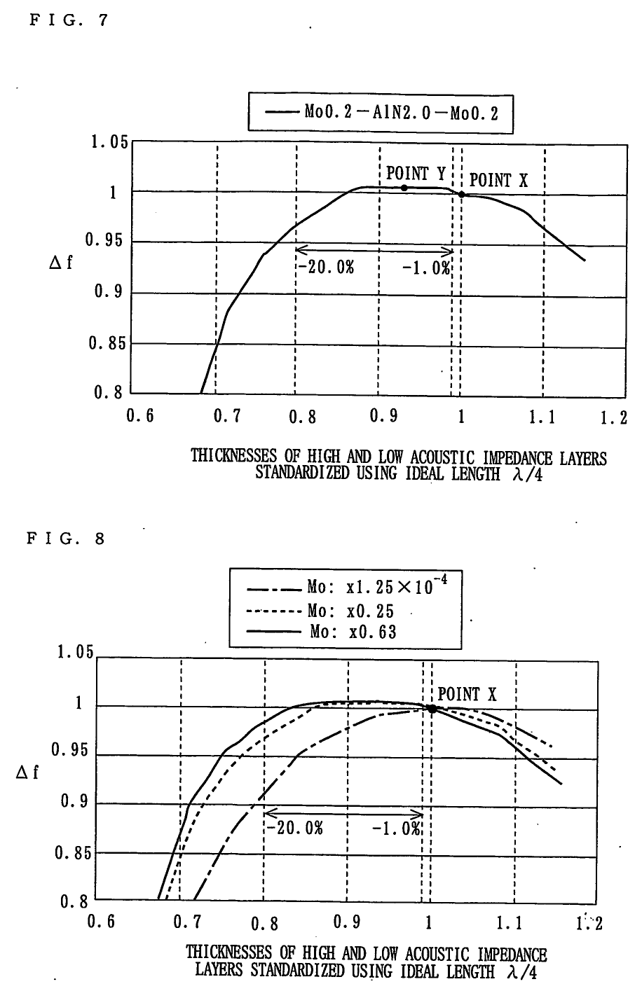

Further, the present inventors found that the effect of the present invention is obtained to a further extent with an increase in the thicknesses of the upper and lower electrodes. FIG. 8 is a graph for explaining that the effect of the present invention is obtained to a further extent with an increase in the thicknesses of the upper and lower electrodes.

In FIG. 8, the thicknesses of the high acoustic impedance layer 302b and the low acoustic impedance layer 303b are changed simultaneously at the same rate, and resonance bands Δf are compared when the thickness of the lower electrode 104b made of molybdenum (Mo) and the thickness of the upper electrode 106b made of molybdenum (Mo) are simultaneously changed to 1.25×10⁻⁴ times, 0.25 times or 0.63 times the acoustic wavelength calculated from the resonant frequency.

In FIG. 8, the horizontal axis represents a value obtained by standardizing the thicknesses of the high acoustic impedance layer 302b and the low acoustic impedance layer 303b using the ideal length λ/4. The vertical axis represents a value obtained by standardizing a change in a resonance bandwidth using a bandwidth (Δf) which is obtained when the thicknesses of the high acoustic impedance layer 302b and the low acoustic impedance layer 303b are each equal to the ideal length λ/4. On the horizontal axis and the vertical axis, a value of 1 is a value which is obtained when the thicknesses of the high acoustic impedance layer 302b and the low acoustic impedance layer 303b are each equal to the ideal length λ/4.

As can be seen from FIG. 8, when the thicknesses of the lower electrode 104b and the upper electrode 106b are increased, the thicknesses of the high acoustic impedance layer 302b and the low acoustic impedance layer 303b when the resonance bandwidth is maximum, are smaller than the ideal length λ/4. Further, it was found that the thicknesses of the high acoustic impedance layer 302b and the low acoustic impedance layer 303b when the resonance bandwidth is maximum, are even smaller than the ideal length λ/4 as the thicknesses of the lower electrode 104b and the upper electrode 106b are increased. It was also found that the thicknesses of the high acoustic impedance layer 302b and the low acoustic impedance layer 303b when the resonance bandwidth is maximum, are in the range of [the ideal length λ/4 minus 40%] to [the ideal length λ/4 minus 1.0%].

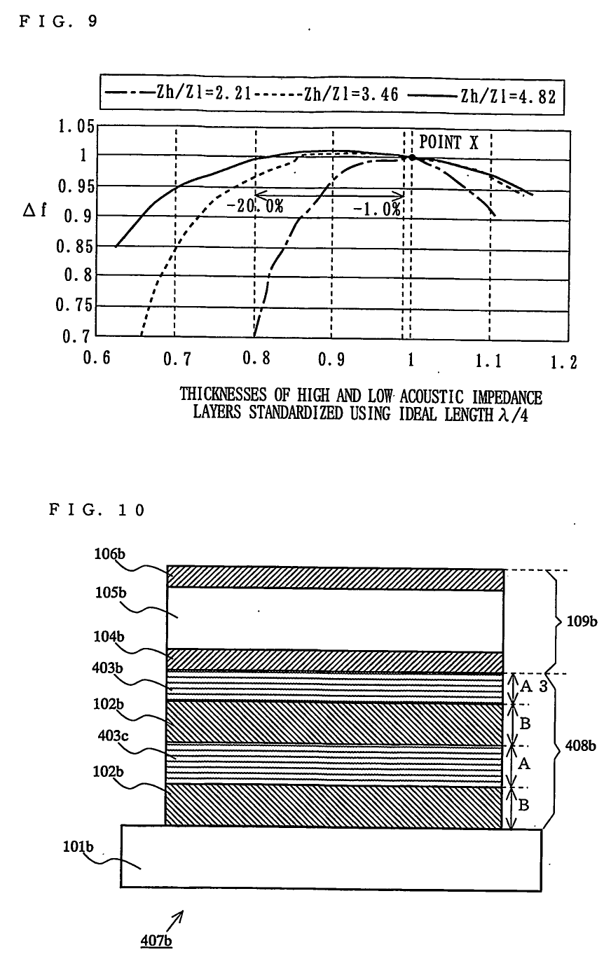

Further, the present inventors found that, the effect of the present invention is obtained to a further extent with an increase in the ratio of the acoustic impedance of the high acoustic impedance layer 302b to the acoustic impedance of the low acoustic impedance layer 303b (the acoustic impedance of the high acoustic impedance layer 302b÷the acoustic impedance of the low acoustic impedance layer 303b). FIG. 9 is a graph showing for explaining that the effect of the present invention is obtained to a further extent with an increase in the ratio of the acoustic impedance of the high acoustic impedance layer 302b to the acoustic impedance of the low acoustic impedance layer 303b.

In FIG. 9, the thickness of the high acoustic impedance layer 302b and the thickness of the low acoustic impedance layer 303b are changed simultaneously at the same rate. The results of the following three cases are compared: a ratio Zh/Zl of an acoustic impedance Zh of the high acoustic impedance layer 302b to an acoustic impedance Zl of the low acoustic impedance layer 303b in the acoustic mirror layer is 2.21 (the high acoustic impedance layer 302b is made of AlN and the low acoustic impedance layer 303b is made of Mo); the ratio Zh/Zl is 3.46 (the high acoustic impedance layer 302b is made of SiO₂ and the low acoustic impedance layer 303b is made of Mo); and the ratio Zh/Zl is 4.82 (the high acoustic impedance layer 302b is made of SiO₂ and the low acoustic impedance layer 303b is made of W).

In FIG. 9, the horizontal axis represents a value obtained by standardizing the thicknesses of the high acoustic impedance layer 302b and the low acoustic impedance layer 303b using the ideal length λ/4. The vertical axis represents a value obtained by standardizing a change in a resonance bandwidth using a bandwidth (Δf) which is obtained when the thicknesses of the high acoustic impedance layer 302b and the low acoustic impedance layer 303b are each equal to the ideal length λ/4. On the horizontal axis and the vertical axis, a value of 1 is a value which is obtained when the thicknesses of the high acoustic impedance layer 302b and the low acoustic impedance layer 303b are each equal to the ideal length λ/4.

As can be seen from FIG. 9, it was found that as the acoustic impedance ratio is increased, the rate of a degradation in resonance band with respect to a change in the thicknesses of the high acoustic impedance layer 302b and the low acoustic impedance layer 303b , is reduced.

Thus, according to the third embodiment, by selecting materials for the high acoustic impedance layer and the low acoustic impedance layer so that their acoustic impedance ratio is high and determining the thicknesses of the high acoustic impedance layer and the low acoustic impedance layer at the point Y which maximizes the resonance band, it is possible to minize a degradation in resonance band due to a variation in the thickness.

In the third embodiment, a low acoustic impedance layer is provided immediately below the lower electrode, and therebelow, high acoustic impedance layer(s) and low acoustic impedance layer(s) are alternately provided. Alternatively, a high acoustic impedance layer may be provided immediately below the lower electrode, and therebelow, low acoustic impedance layer(s) and high acoustic impedance layer(s) may be alternately provided.

### Fourth Embodiment

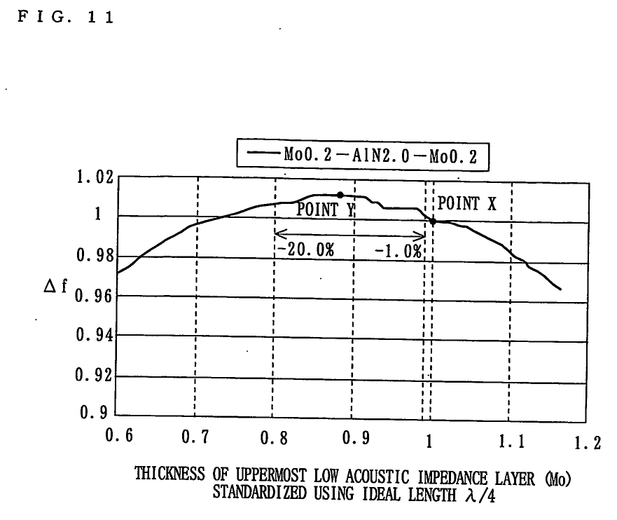

FIG. 10 is a cross-sectional view of an acoustic mirror type thin film bulk acoustic resonator according to a fourth embodiment of the present invention. In FIG. 10, the acoustic mirror type thin film bulk acoustic resonator 407b comprises a substrate 101b, high acoustic impedance layers 102b, an uppermost low acoustic impedance layer 403b, a low acoustic impedance layer 403c, a lower electrode 104b, a piezoelectric thin film 105b, and an upper electrode 106b. In FIG. 10, the same parts as those of the first embodiment are referenced with the same reference numerals and will not be explained.

The number of the high acoustic impedance layers 102b is two in FIG. 10, or alternatively, may be three or more. Also, the total number of the uppermost low acoustic impedance layer 403b and the low acoustic impedance layer 403c is two in FIG. 10, or alternatively, may be three or more. Note that an uppermost one of the low acoustic impedance layers 403b is formed immediately below the lower electrode 104b.

An acoustic mirror layer 408b, which is composed of the high acoustic impedance layers 102b, the uppermost low acoustic impedance layer 403b and the low acoustic impedance layers 403c, is provided on the substrate 101b. On the acoustic mirror layer 408b, a piezoelectric thin film vibrator 109b, which is composed of the lower electrode 104b, the piezoelectric thin film 105b and the upper electrode 106b, is provided.

The uppermost low acoustic impedance layer 403b is made of a low acoustic impedance material, such as silicon dioxide (SiO₂) or the like. A thickness (A3) of the uppermost low acoustic impedance layer 403b is smaller than the size of one fourth of an acoustic wavelength calculated from a resonant frequency (antiresonant frequency) in free space of the piezoelectric thin film vibrator 109b.

The low acoustic impedance layer 403c is made of a low acoustic impedance material, such as silicon dioxide (SiO₂) or the like. A thickness (A) of the low acoustic impedance layer 403c is equal to the size of one fourth of the acoustic wavelength calculated from the resonant frequency (antiresonant frequency) in free space of the piezoelectric thin film vibrator 109b.

FIG. 11 is a graph showing a change in resonance band when the thickness of the uppermost low acoustic impedance layer 403b is changed while fixing the other values. In FIG. 11, the horizontal axis represents a value obtained by standardizing the thickness of the uppermost acoustic impedance layer 403b using the ideal length λ/4. The vertical axis represents a value obtained by standardizing a change in a resonance bandwidth using a bandwidth (Δf) which is obtained when the thickness of the uppermost acoustic impedance layer 403b is equal to the ideal length λ/4. On the horizontal axis and the vertical axis, a value of 1 is a value which is obtained when the thickness of the high acoustic impedance layer 202b is equal to the ideal length λ/4.

As can be seen from FIG. 11, the thickness of the uppermost acoustic impedance layer 403b which maximizes the resonance bandwidth is obtained at a thickness point Y which is smaller than a thickness point X corresponding to the ideal length λ/4. Therefore, the thickness of the uppermost acoustic impedance layer 403b is preferably smaller than the size of one fourth of the acoustic wavelength which is calculated from the resonant frequency (antiresonant frequency) in free space of the piezoelectric thin film vibrator 109b.

For example, the degree of a change in resonance bandwidth at the point X is compared with the degree of a change in resonance bandwidth at the point Y, assuming that there is, for example, a variation of ±1% in thickness. In this case, it will be found that the change degree is smaller at the point Y than at the point X. Therefore, when the thickness at the point Y is determined to be the thickness (A3) of the uppermost acoustic impedance layer 403b, a change in resonance band due to a variation in thickness can be further reduced. Thereby, an influence of the thickness variation can be minimized.

Also as can be seen from FIG. 11, the thickness of the uppermost acoustic impedance layer 403b is preferably in the range of [the ideal length λ/4 minus 20.0%] to [the ideal length λ/4 minus 1.0%].

The principle of why the thickness of the uppermost acoustic impedance layer 403b is preferably smaller than the size of one fourth of the acoustic wavelength which is calculated from the resonant frequency (antiresonant frequency) in free space of the piezoelectric thin film vibrator 109b, is similar to that of the first embodiment.

Thus, according to the second embodiment, by setting the thickness of the uppermost low acoustic impedance layer of the acoustic mirror layers in the acoustic mirror type thin film bulk acoustic resonator to be smaller than the size of one fourth of an acoustic wavelength calculated from the resonant frequency (antiresonant frequency) in free space of the piezoelectric thin film vibrator, the resonance bandwidth can be broadened. By broadening the resonance bandwidth, it is possible to prevent a degradation in resonance characteristics due to variations in the thickness of the uppermost low acoustic impedance layer.

### (Fifth embodiment)

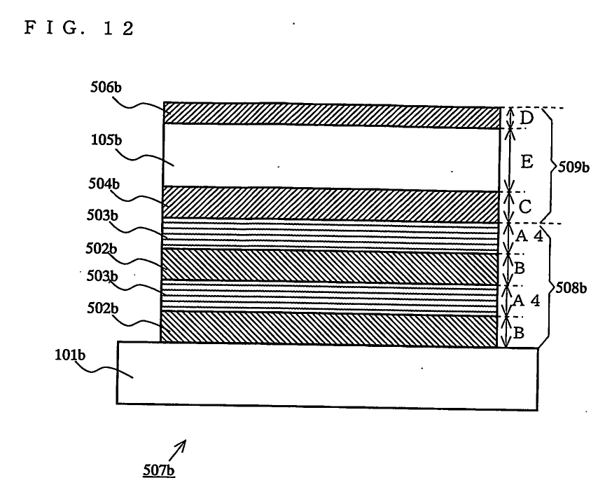

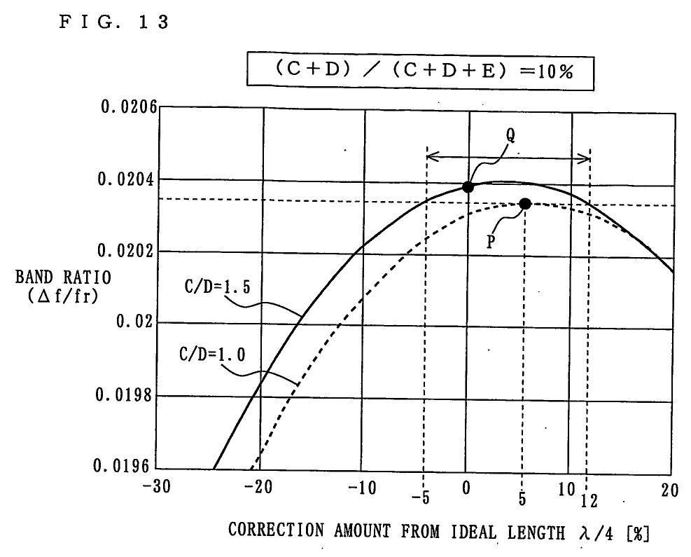

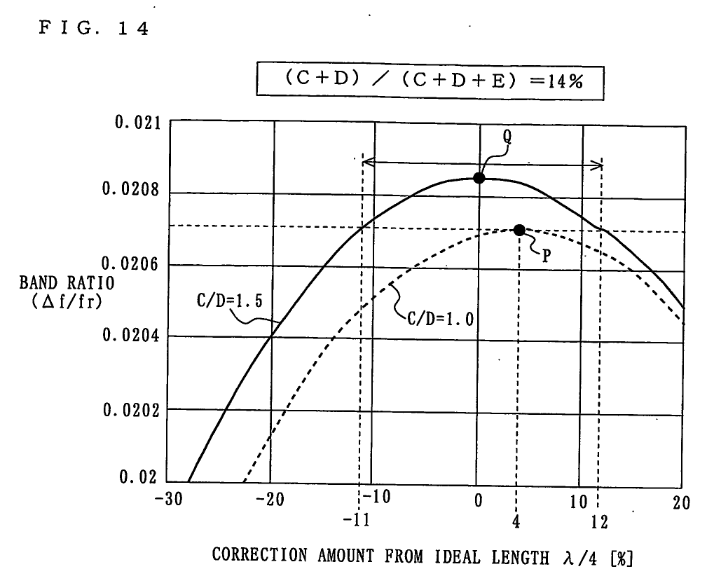

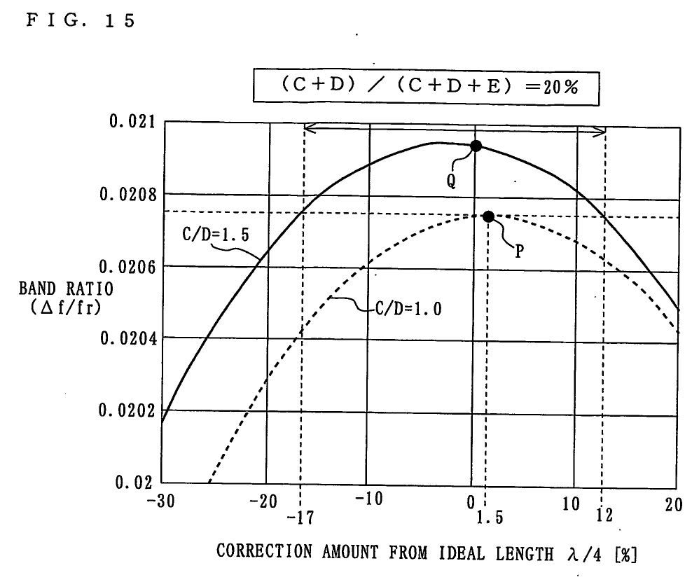

FIG. 12 is a cross-sectional view of an acoustic mirror type thin film bulk acoustic resonator according to a fifth embodiment of the present invention. In FIG. 12, the acoustic mirror type thin film bulk acoustic resonator 507b comprises a substrate 101b, high acoustic impedance layers 502b, low acoustic impedance layers 503b, a lower electrode 504b, a piezoelectric thin film 105b, and an upper electrode 506b. In FIG. 12, the same parts as those of the first embodiment are referenced with the same reference numerals and will not be explained.

The number of the high acoustic impedance layers 502b is two in FIG. 12, or alternatively, may be one, or three or more. Also, the number of the low acoustic impedance layers 503b is two in FIG. 12, or alternatively, may be one, or three or more. Note that an uppermost one of the low acoustic impedance layers 503b is formed immediately below the lower electrode 504b. The low acoustic impedance layers 503b and the high acoustic impedance layers 502b are alternately formed in the same number.

An acoustic mirror layer 508b, which is composed of the high acoustic impedance layers 502b and the low acoustic impedance layers 503b, is provided on the substrate 101b. On the acoustic mirror layer 508b, a piezoelectric thin film vibrator 509b, which is composed of the lower electrode 504b, the piezoelectric thin film 105b and the upper electrode 506b, is provided.

The low acoustic impedance layer 503b is made of a low acoustic impedance material, such as silicon dioxide (SiO₂) or the like. A thickness (A4) of the low acoustic impedance layer 503b is smaller than, larger than, or equal to the size of one fourth of an acoustic wavelength calculated from a resonant frequency (antiresonant frequency) in free space of the piezoelectric thin film vibrator 509b.

The high acoustic impedance layer 502b is made of a high acoustic impedance material, such as tungsten (W), molybdenum (Mo) or the like. A thickness (B) of the high acoustic impedance layer 502b is smaller than, larger than, or equal to the size of one fourth of the acoustic wavelength calculated from the resonant frequency (antiresonant frequency) in free space of the piezoelectric thin film vibrator 509b.

The lower electrode 504b is made of, for example, molybdenum (Mo), aluminum (Al), platinum (Pt), gold (Au) or the like.

The upper electrode 506b is made of, for example, molybdenum (Mo), aluminum (Al), platinum (Pt), gold (Au), or the like.

A thickness (C) of the lower electrode 504b is larger than a thickness (D) of the upper electrode 506b. In other words, C/D>1.0. Hereinafter, the ratio (C/D) of the thickness of the lower electrode 504b to the thickness of the upper electrode 506b is referred to as an “upper/lower ratio”.

The present inventors studied what proportion of the sum (C+D) of the thickness (C) of the lower electrode 504b and the thickness (D) of the upper electrode 506b with respect to the whole thickness (C+D+E) of the piezoelectric thin film vibrator 509b, can broaden the resonance bandwidth. The proportion is represented as (C+D)/(C+D+E). Hereinafter, the proportion (C+D)/(C+D+E) is referred to as an electrode ratio.

FIG. 13 is a graph showing a band ratio when the electrode ratio is 10%. In FIG. 13, the horizontal axis represents a thickness of the low acoustic impedance layer 503b as a correction amount from the ideal length λ/4. On the horizontal axis, “0” indicates when the low acoustic impedance layer 503b has a thickness of λ/4. On the horizontal axis, “−10”, “−20” and “−30” indicate when the low acoustic impedance layer 503b has a thickness of [λ/4 minus 10%, 20% and 30%], respectively. On the horizontal axis, “10” and “20” indicate when the low acoustic impedance layer 503b has a thickness of [λ/4 plus 10% and 20%], respectively. The vertical axis represents a band ratio. The band ratio is a ratio (Δf/fr) of a bandwidth Δf to a resonant frequency fr. If the resonant frequency fr is assumed to be constant, the larger the band ratio, the larger the bandwidth Δf. In FIG. 13, a dashed line indicates when the thickness (C) of the lower electrode is equal to the thickness (D) of the upper electrode as in the first to fourth embodiments, i.e., the ratio (C/D) of the thickness of the lower electrode to the thickness of the upper electrode is 1.0. A solid line indicates when the thickness of the lower electrode is 1.5 times the thickness of the upper electrode, i.e., C/D is 1.5.

When the thickness of the upper electrode is equal to the thickness of the lower electrode (C/D=1.0), the band ratio is maximum if the thickness of the low acoustic impedance layer is larger by 5% than the ideal length λ/4 (see a point P). On the other hand, when the thickness of the lower electrode is 1.5 times the thickness of the upper electrode (C/D=1.5), the band ratio is larger than when C/D=1.0 even if the thickness of the low acoustic impedance layer is equal to the ideal length λ/4 (see a point Q). Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 13, when the thickness of the lower electrode is larger than the thickness of the upper electrode, the band ratio is larger than when the thickness of the lower electrode is equal to the thickness of the upper electrode, if the thickness of the low acoustic impedance layer is in the range of [the ideal length λ/4 minus 5%] to [the ideal length λ/4 plus 12%].

Therefore, preferably, when the thickness of the lower electrode is larger than the thickness of the upper electrode and the thickness of the low acoustic impedance layer is increased, the band ratio can be increased.

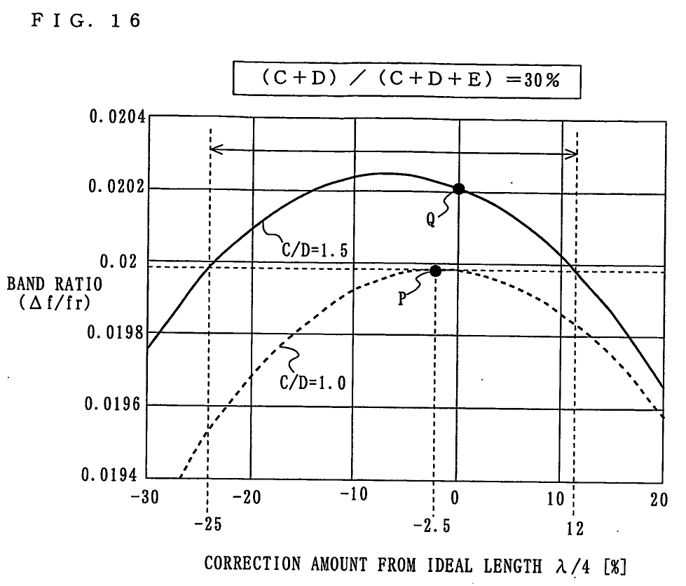

FIG. 14 is a graph showing a band ratio when the electrode ratio is 14%. When the thickness of the upper electrode is equal to the thickness of the lower electrode (C/D=1.0), the band ratio is maximum if the thickness of the low acoustic impedance layer is larger by 4% than the ideal length λ/4 (see a point P). On the other hand, when the thickness of the lower electrode is 1.5 times the thickness of the upper electrode (C/D=1.5), the band ratio is larger than when C/D=1.0 even if the thickness of the low acoustic impedance layer is equal to the ideal length λ/4 (see a point Q). Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 14, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 11%] to [the ideal length λ/4 plus 12%].

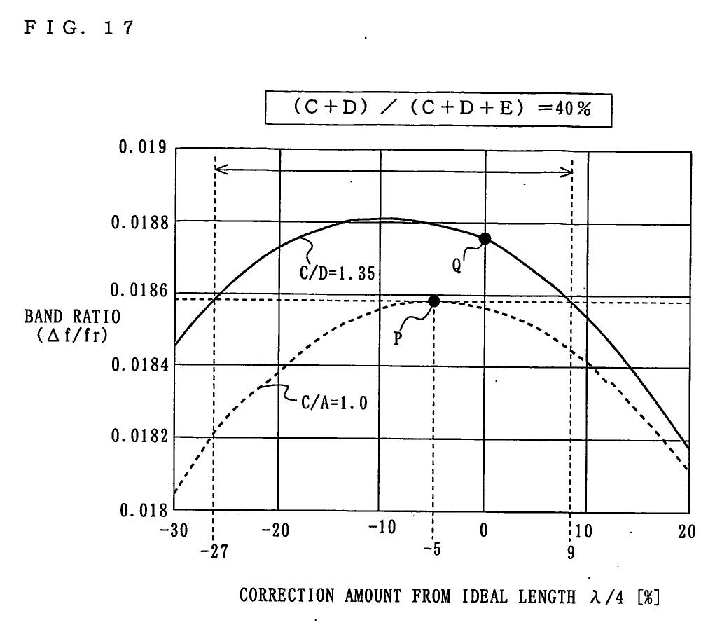

FIG. 15 is a graph showing a band ratio when the electrode ratio is 20%. When the thickness of the upper electrode is equal to the thickness of the lower electrode (C/D=1.0), the band ratio is maximum if the thickness of the low acoustic impedance layer is larger by 1.5% than the ideal length λ/4 (see a point P). On the other hand, when the thickness of the lower electrode is 1.5 times the thickness of the upper electrode (C/D=1.5), the band ratio is larger than when C/D=1.0 even if the thickness of the low acoustic impedance layer is equal to the ideal length λ/4 (see a point Q). Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 15, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 17%) to [the ideal length λ/4 plus 12%].

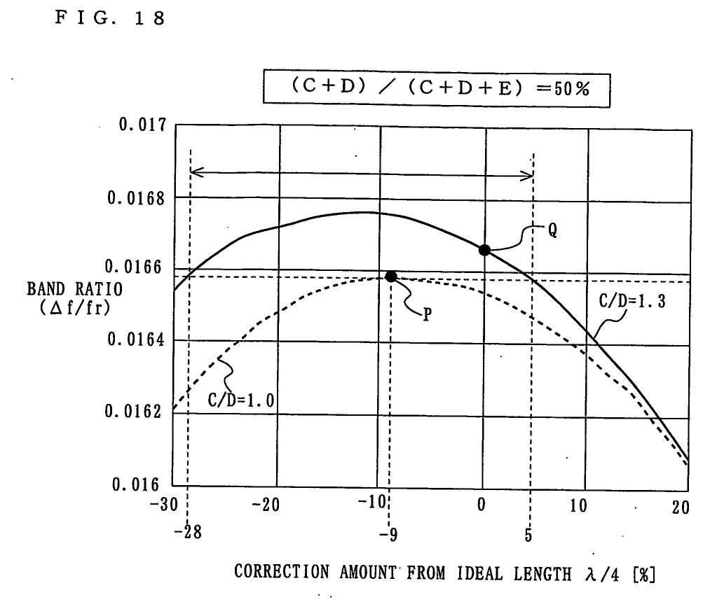

FIG. 16 is a graph showing a band ratio when the electrode ratio is 30%. When the thickness of the upper electrode is equal to the thickness of the lower electrode (C/D=1.0), the band ratio is maximum if the thickness of the low acoustic impedance layer is smaller by 2.5% than the ideal length λ/4 (see a point P). On the other hand, when the thickness of the lower electrode is 1.5 times the thickness of the upper electrode (C/D=1.5), the band ratio is larger than when C/D=1.0 even if the thickness of the low acoustic impedance layer is equal to the ideal length λ/4 (see a point Q) Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 16, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 25%] to [the ideal length λ/4 plus 12%).

Therefore, preferably, when the thickness of the lower electrode is larger than the thickness of the upper electrode and the thickness of the low acoustic impedance layer is decreased, the band ratio can be increased.

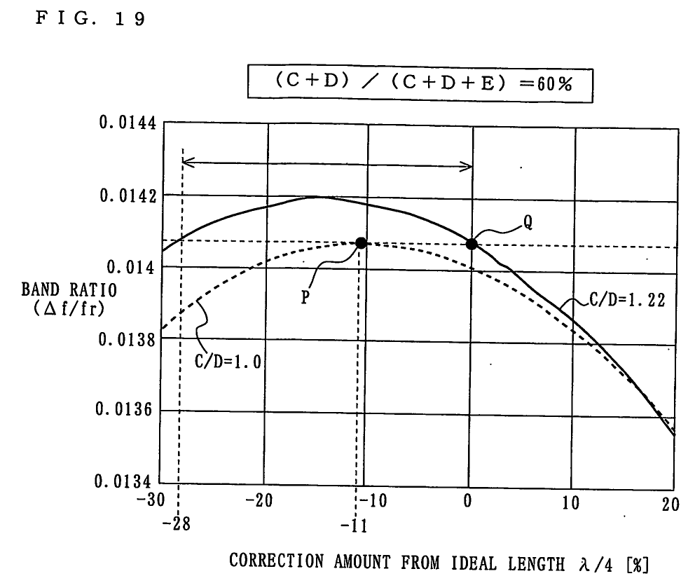

FIG. 17 is a graph showing a band ratio when the electrode ratio is 40%. When the thickness of the upper electrode is equal to the thickness of the lower electrode (C/D=1.0), the band ratio is maximum if the thickness of the low acoustic impedance layer is smaller by 5% than the ideal length λ/4 (see a point P). On the other hand, when the thickness of the lower electrode is 1.35 times the thickness of the upper electrode (C/D=1.35), the band ratio is larger than when C/D=1.0 even if the thickness of the low acoustic impedance layer is equal to the ideal length λ/4 (see a point Q). Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 17, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 27%] to [the ideal length λ/4 plus 9%].

Therefore, preferably, when the thickness of the lower electrode is larger than the thickness of the upper electrode and the thickness of the low acoustic impedance layer is decreased, the band ratio can be increased.

FIG. 18 is a graph showing a band ratio when the electrode ratio is 50%. When the thickness of the upper electrode is equal to the thickness of the lower electrode (C/D=1.0), the band ratio is maximum if the thickness of the low acoustic impedance layer is smaller by 9% than the ideal length λ/4 (see a point P). On the other hand, when the thickness of the lower electrode is 1.3 times the thickness of the upper electrode (C/D=1.3), the band ratio is larger than when C/D=1.0 even if the thickness of the low acoustic impedance layer is equal to the ideal length λ/4 (see a point Q). Therefore, when the thickness of the lower electrode is set to be larger than the thickness of the upper electrode without adjustment of the thickness of the low acoustic impedance layer, the band ratio is larger than when only the thickness of the low acoustic impedance layer is optimized.

As can be seen from FIG. 18, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 28%] to [the ideal length λ/4 plus 5%].

Therefore, preferably, when the thickness of the lower electrode is larger than the thickness of the upper electrode and the thickness of the low acoustic impedance layer is decreased, the band ratio can be increased.

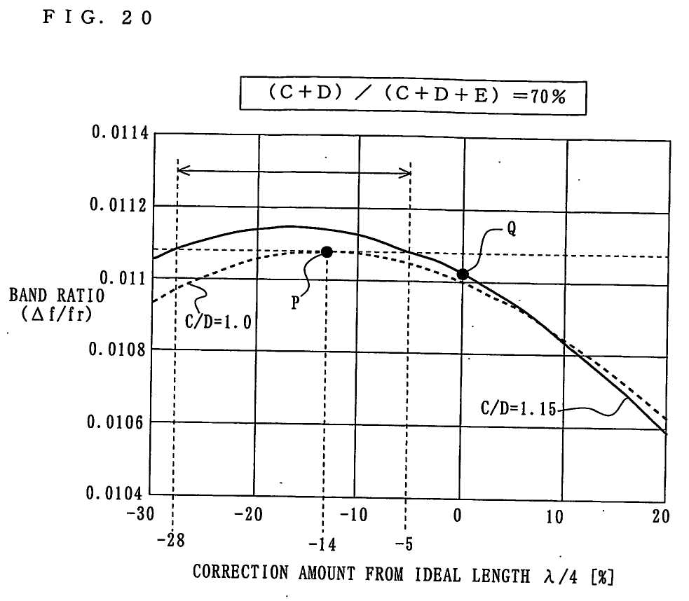

FIG. 19 is a graph showing a band ratio when the electrode ratio is 60%. When the thickness of the upper electrode is equal to the thickness of the lower electrode (C/D=1.0), the band ratio is maximum if the thickness of the low acoustic impedance layer is smaller by 11% than the ideal length λ/4 (see a point P). On the other hand, when the thickness of the lower electrode is 1.22 times the thickness of the upper electrode (C/D=1.22), the band ratio is about the same as when C/D=1.0 even if the thickness of the low acoustic impedance layer is equal to the ideal length λ/4 (see a point Q). Therefore, the effect obtained only when the thickness of the lower electrode is set to be larger than the thickness of the upper electrode, is no longer obtained if the band ratio is larger than 60%.

However, as can be seen from FIG. 19, when the thickness of the lower electrode is larger than the thickness of the upper electrode, the band ratio is larger than when the thickness of the lower electrode is equal to the thickness of the upper electrode if the thickness of the low acoustic impedance layer is in the range of [the ideal length λ/4 minus 28%] to [the ideal length λ/4 plus 0%]. Therefore, preferably, when the thickness of the lower electrode is larger than the thickness of the upper electrode and the thickness of the low acoustic impedance layer is decreased, the band ratio can be increased.

FIG. 20 is a graph showing a band ratio when the electrode ratio is 70%. When the thickness of the upper electrode is equal to the thickness of the lower electrode (C/D=1.0), the band ratio is maximum if the thickness of the low acoustic impedance layer is smaller by 14% than the ideal length λ/4 (see a point P). On the other hand, when the thickness of the lower electrode is 1.15 times the thickness of the upper electrode (C/D=1.15), the band ratio obtained when the thickness of the low acoustic impedance layer is equal to the ideal length λ/4 is smaller than the maximum band ratio obtained when C/D=1.0 (see a point Q). Therefore, when the electrode ratio is 70%, the band ratio cannot be increased only by setting the thickness of the lower electrode to be larger than the thickness of the upper electrode. However, as can be seen from FIG. 20, when the thickness of the lower electrode is larger than the thickness of the upper electrode and the thickness of the low acoustic impedance layer is in the range of [the ideal length λ/4 minus 28%] to [the ideal length λ/4 minus 5%], the band ratio is larger than when the thickness of the lower electrode is equal to the thickness of the upper electrode. Therefore, it will be understood that, when the thickness of the lower electrode is larger than the thickness of the upper electrode and the thickness of the low acoustic impedance layer is decreased, the band ratio can be increased.

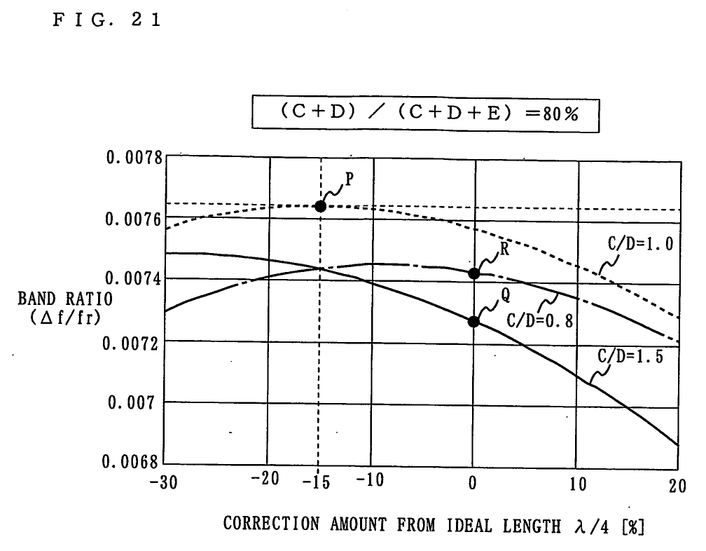

FIG. 21 is a graph showing a band ratio when the electrode ratio is 80%. In the graph of FIG. 21, when the thickness of the upper electrode is equal to the thickness of the lower electrode (C/D=1.0), the band ratio is maximum if the thickness of the low acoustic impedance layer is equal to [the ideal length λ/4 minus 15%] (see a point P). On the other hand, when the thickness of the lower electrode is 1.5 times the thickness of the upper electrode (C/D=1.5) or 0.8 times (C/D=0.8), a band ratio larger than when C/D=1.0 cannot be obtained if the thickness of the low acoustic impedance layer is equal to the ideal length λ/4. Therefore, when the electrode ratio is 80%, the band ratio cannot be increased only by setting the thickness of the lower electrode to be larger or smaller than the thickness of the upper electrode (see points P and Q).

As shown in FIG. 21, when the thickness of the lower electrode is larger than the thickness of the upper electrode or when the thickness of the lower electrode is smaller than the thickness of the upper electrode, conditions under which a band ratio exceeding the maximum ratio when C/D=1.0 cannot be obtained even if the thickness of the low acoustic impedance layer is adjusted. Therefore, when the electrode ratio is 80%, the band ratio cannot be increased by setting the thickness of the lower electrode to be larger or smaller than the thickness of the upper electrode. However, by setting the thickness of the lower electrode to be equal to the thickness of the upper electrode and adjusting the thickness of the low acoustic impedance layer, the band ratio can be increased. Therefore, an upper limit value of the electrode ratio is estimated to be 80%.

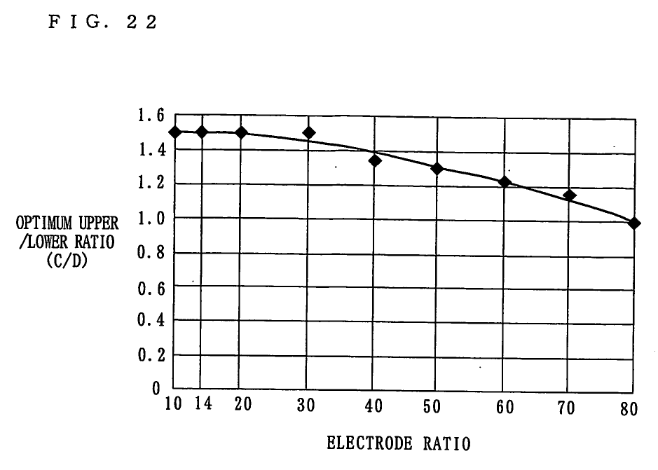

FIG. 22 is a graph showing an optimum value of the upper/lower ratio. In FIG. 22, the horizontal axis represents the electrode ratio. The vertical axis represents an optimum value of the upper/lower ratio when the electrode ratio indicated by the horizontal axis is used. The optimum value of the upper/lower ratio indicated by the vertical axis is an upper/lower ratio which can provide a maximum band ratio by adjusting the thickness of the low acoustic impedance layer. For example, as shown in FIG. 20, when the electrode ratio is 70%, by setting the upper/lower ratio to be 1.15 and the thickness of the low acoustic impedance layer to be (the ideal length λ/4 minus about 15%], a maximum band ratio can be obtained. In FIG. 22, the upper/lower ratio thus set is shown. In FIG. 22, maximum values of the upper/lower ratio are plotted with diamonds, which are obtained when the electrode ratio is 10%, 14%, 20%, 30%, 40%, 50%, 60%, 70% and 80%, respectively, and a curve interpolates between each diamond.

As shown in FIG. 22, when the electrode ratio is 80%, the optimum upper/lower ratio is 1.0. According to FIGS. 21 and 22, it will be understood that, when the electrode ratio is 80%, the band ratio cannot be increased by adjusting the thickness of the lower electrode, however, the band ratio canbe increasedby setting the thickness of the lower electrode to be equal to the thickness of the upper electrode and adjusting the thickness of the low acoustic impedance layer. Therefore, when the electrode ratio is 60% or more and less than 80%, the band ratio cannot be increased only by adjusting the thickness of the lower electrode, however, the band ratio can be increased by setting the thickness of the lower electrode to be thicker than the upper electrode and adjusting the thickness of the low impedance layer.

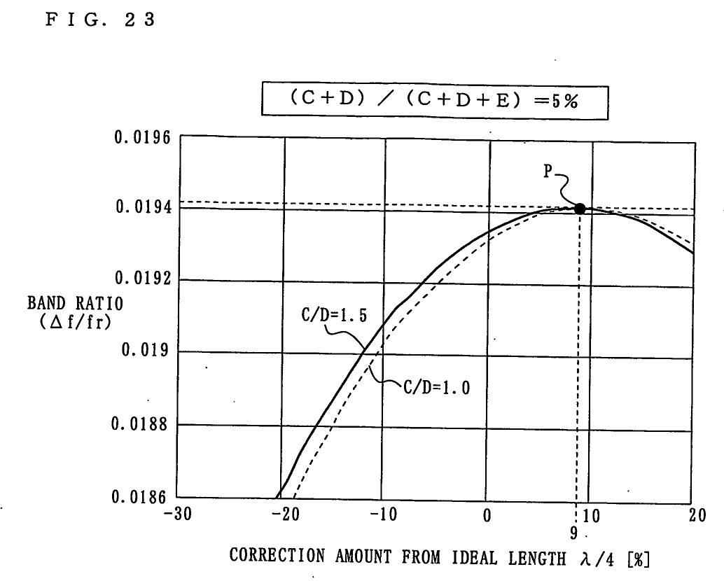

FIG. 23 is a graph showing a band ratio when the electrode ratio is 5%. In FIG. 23, a band ratio obtained when the thickness of the upper electrode is equal to the thickness of the lower electrode (C/D=1.0) and a band ratio obtained when the thickness of the lower electrode is 1.5 times the thickness of the upper electrode (C/D=1.5), are shown. In the case of C/D=1.0, the band ratio is maximum when the thickness of the low acoustic impedance layer is [the ideal length λ/4 plus 9%] (see apoint P). Similarly, in the case of C/D=1.5, the band ratio is maximum when the thickness of the low acoustic impedance layer is [the ideal length λ/4 plus 9%] (see a point P). Therefore, when the electrode ratio is 5% and C/D is 1.5, there are no conditions under which a maximum band ratio exceeds that obtained when C/D=1.0. Therefore, when the electrode ratio is 5%, the band ratio cannot be increased by increasing the lower electrode or adjusting the thickness of the low acoustic impedance layer. Therefore, the lower limit of the electrode ratio is estimated to be 5%.

According to the first to fifth embodiments, it will be understood as follows.

As shown with the points Q in FIGS. 13 to 19 and the points P in FIG. 23, in the piezoelectric thin film vibrator, the sum of the thickness of the lower electrode and the thickness of the upper electrode is 5% or more and 60% or less of the thickness of the piezoelectric thin film vibrator and the thickness of the lower electrode is larger than the thickness of the upper electrode. In this case, the thin film bulk acoustic resonator has a band ratio which is larger than or equal to a maximum band ratio obtained in a thin film bulk acoustic resonator in which the thickness of the lower electrode is equal to the thickness of the upper electrode.

As shown with the points Q in FIGS. 13 to 19 and the points P in FIG. 23, in the case where the electrode ratio is 5% or more and 60% or less, even when all the low acoustic impedance layers have a thickness of λ/4, it is possible to obtain a band ratio which is larger than or equal to a maximum band ratio obtained in a thin film bulk acoustic resonator in which the thickness of the lower electrode is equal to the thickness of the upper electrode. In this case, as shown in FIG. 11 in the fourth embodiment, it is estimated that, even when only the uppermost low acoustic impedance layer has a thickness of λ/4, it is possible to obtain a band ratio which is larger than or equal to a maximum band ratio obtained in a thin film bulk acoustic resonator in which the thickness of the lower electrode is equal to the thickness of the upper electrode.

As shown in FIGS. 13 to 19, in the case where the electrode ratio is 5% or more and 60% or less, even when all the low acoustic impedance layers have a thickness of less than λ/4, it is possible to obtain a band ratio which is larger than or equal to a maximum band ratio obtained in a thin film bulk acoustic resonator in which the thickness of the lower electrode is equal to the thickness of the upper electrode. As shown in FIGS. 15 to 19, by setting the thickness of the low acoustic impedance layer to be less than λ/4, a band ratio which is higher than when the thickness of the low acoustic impedance layer is equal to λ/4, may be obtained. In this case, as shown in FIG. 11 in the fourth embodiment, it is estimated that, even when only the uppermost low acoustic impedance layer has a thickness of less than λ/4, it is possible to obtain a band ratio which is larger than or equal to a maximum band ratio obtained in a thin film bulk acoustic resonator in which the thickness of the lower electrode is equal to the thickness of the upper electrode.

As shown in FIGS. 13 to 19, in the case where the electrode ratio is 5% or more and 60% or less, even when all the low acbustic impedance layers have a thickness of more than λ/4, it is possible obtain a band ratio which is larger than or equal to a maximum band ratio obtained in a thin film bulk acoustic resonator in which the thickness of the lower electrode is equal to the thickness of the upper electrode. As shown in FIG. 13, by setting the thickness of the low acoustic impedance layer to be more than λ/4, a band ratio which is higher than when the thickness of the low acoustic impedance layer is equal to π/4, may be obtained. In this case, it is estimated that, even when only the uppermost low acoustic impedance layer has a thickness of more than λ/4, it is possible to obtain a band ratio which is larger than or equal to a maximum band ratio obtained in a thin film bulk acoustic resonator in which the thickness of the lower electrode is equal to the thickness of the upper electrode.

In the examples of FIGS. 13 to 16, the thickness of the low acoustic impedance layer is adjusted. However, when the electrode ratio is 5% or more and 60% or less and the thickness of the lower electrode is larger than the thickness of the upper electrode, by setting the thickness of the high acoustic impedance layer to be less than λ/4 as in the second embodiment, it is possible to obtain a band ratio which is larger than or equal to a maximum band ratio obtained in a thin film bulk acoustic resonator in which the thickness of the lower electrode is equal to the thickness of the upper electrode. Further, according to the example of FIG. 13, by setting the thickness of the high acoustic impedance layer to be more than λ/4, it is possible to obtain a band ratio which is larger than or equal to a maximum band ratio obtained in a thin film bulk acoustic resonator in which the thickness of the lower electrode is equal to the thickness of the upper electrode. Therefore, even when the thickness of the high acoustic impedance layer is different from λ/4, it is possible to obtain a band ratio which is larger than or equal to a maximum band ratio obtained in a thin film bulk acoustic resonator in which the thickness of the lower electrode is equal to the thickness of the upper electrode. It will be understood from the third embodiment that, when the thickness of the high acoustic impedance layer is different from λ/4, the thickness of the low acoustic impedance layer may be different from λ/4. In this case, at least the uppermost low acoustic impedance layer may have a thickness different from λ/4.

According to FIG. 13, in the case where the electrode ratio is 10%, if the upper/lower ratio is 1.5 and the thickness of the low acoustic impedance layer is between [λ/4 minus 5%] (inclusive) and [λ/4 plus 12%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 14, in the case where the electrode ratio is 14%, if the upper/lower ratio is 1.5 and the thickness of the low acoustic impedance layer is between [λ/4 minus 11%] (inclusive) and [λ/4 plus 12%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 15, in the case where the electrode ratio is 20%, if the upper/lower ratio is 1.5 and the thickness of the low acoustic impedance layer is between [λ/4 minus 17%] (inclusive) and [λ/4 plus 12%] (inclusive), it is possible to obtain a band ratio which is larger than or equal to a maximum band ratio obtained in a thin film bulk acoustic resonator in which the thickness of the lower electrode is equal to the thickness of the upper electrode.

As shown in FIGS. 14 and 15, in a thin film bulk acoustic resonator having an electrode ratio of 14% to 20%, the band ratio can be set to be 0.0208 or more by adjusting the thickness of the low acoustic impedance layer. Thus, a preferable band ratio can be obtained.

According to FIG. 16, in the case where the electrode ratio is 30%, if the upper/lower ratio is 1.5 and the thickness of the low acoustic impedance layer is between [λ/4 minus 25%] (inclusive) and [λ/4 plus 12%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 17, in the case where the electrode ratio is 40%, if the upper/lower ratio is 1.35 and the thickness of the low acoustic impedance layer is between [λ/4 minus 27%] (inclusive) and [λ/4 plus 9%) (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 18, in the case where the electrode ratio is 50%, if the upper/lower ratio is 1.3 and the thickness of the low acoustic impedance layer is between [λ/4 minus 28%] (inclusive) and [λ/4 plus 5%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 19, in the case where the electrode ratio is 60%, if the upper/lower ratio is 1.22 and the thickness of the low acoustic impedance layer is between [λ/4 minus 28%] (inclusive) and [λ/4 plus 0%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 20, in the case where the electrode ratio is 70%, if the upper/lower ratio is 1.15 and the thickness of the low acoustic impedance layer is between [λ/4 minus 28%] (inclusive) and [λ/4 minus 5%] (inclusive), it is possible to obtain a band ratio which is larger than or equal to a maximum band ratio obtained in a thin film bulk acoustic resonator in which the thickness of the lower electrode is equal to the thickness of the upper electrode.

According to FIG. 21, in the case where the electrode ratio is 80%, if the upper/lower ratio is 1.0 and the thickness of the low acoustic impedance layer is adjusted to be larger or smaller than the ideal length λ/4, the band ratio can be increased.

Further, the embodiments of the present invention include the following concept.

Among the impedance layers constituting the acoustic mirror layer, at least one impedance layer may have a thickness of less than one fourth of an acoustic wavelength determined from a resonant frequency in free space of the piezoelectric thin film vibrator.

Thereby, at least one impedance layer has a thickness of less than one fourth of the acoustic wavelength determined from the resonant frequency in free space of the piezoelectric thin film vibrator, and therefore, the resonance bandwidth can be broadened. By broadening the resonance bandwidth, a deterioration in resonance characteristics due to variations in the thickness of the impedance layer can be prevented.

When a plurality of low acoustic impedance layers and a plurality of high acoustic impedance layers, which are alternately disposed, are provided, the uppermost low acoustic impedance layer may contact the lower electrode and have a thickness of less than one fourth of the acoustic wavelength determined from the resonant frequency in free space of the piezoelectric thin film vibrator. Thereby, the resonance bandwidth can be more effectively broadened.

The uppermost low acoustic impedance layer may have a thickness of [the size of one fourth of the acoustic wavelength determined from the resonant frequency in free space of the piezoelectric thin film vibrator minus 1.0%] or less. Thereby, the resonance bandwidth can be broadened without an influence of variations in the thickness.

The uppermost low acoustic impedance layer may have a thickness of [the size of one fourth of the acoustic wavelength determined from the resonant frequency in free space of the piezoelectric thin film vibrator minus 20.0%] or more. Thereby, the resonance bandwidth can be broadened without an influence of variations in the thickness.

Each low acoustic impedance layer may have a thickness of less than one fourth of the acoustic wavelength determined from the resonant frequency in free space of the piezoelectric thin film vibrator. Thereby, the resonance bandwidth can be more effectively broadened.

Each low acoustic impedance layer may have a thickness of [the size of one fourth of the acoustic wavelength determined from the resonant frequency in free space of the piezoelectric thin film vibrator minus 1.0%] or less. Thereby, the resonance bandwidth can be broadened without an influence of variations in the thickness.

Each low acoustic impedance layer may have a thickness of [the size of one fourth of the acoustic wavelength determined from the resonant frequency in free space of the piezoelectric thin film vibrator minus 20.0%] or more. Thereby, the resonance bandwidth can be broadened without an influence of variations in the thickness.

Each high acoustic impedance layer may have a thickness of less than one fourth of the acoustic wavelength determined from the resonant frequency in free space of the piezoelectric thin film vibrator. Thereby, the resonance bandwidth can be more effectively broadened.

Each high acoustic impedance layer may have a thickness of [the size of one fourth of the acoustic wavelength determined from the resonant frequency in free space of the piezoelectric thin film vibrator minus 1.0%] or less. Thereby, the resonance bandwidth can be broadened without an influence of variations in the thickness.

Each high acoustic impedance layer may have a thickness of [the size of one fourth of the acoustic wavelength determined from the resonant frequency in free space of the piezoelectric thin film vibrator minus 20.0%] or more. Thereby, the resonance bandwidth can be broadened without an influence of variations in the thickness.

Each low acoustic impedance layer may have a thickness of less than one fourth of the acoustic wavelength determined from the resonant frequency in free space of the piezoelectric thin film vibrator and each high acoustic impedance layer may have a thickness of less than one fourth of the acoustic wavelength determined from the resonant frequency in free space of the piezoelectric thin film vibrator. Thereby, the resonance bandwidth can be more effectively broadened.

Each high acoustic impedance layer and each low acoustic impedance layer may have a thickness of [the size of one fourth of the acoustic wavelength determined from the resonant frequency in free space of the piezoelectric thin film vibrator minus 1.0%] or less. Thereby, the resonance bandwidth can be broadened without an influence of variations in the thickness.

Each high acoustic impedance layer and each low acoustic impedance layer may have a thickness of [the size of one fourth of the acoustic wavelength determined from the resonant frequency in free space of the piezoelectric thin film vibrator minus 20.0%] or more. Thereby, the resonance bandwidth can be broadened without an influence of variations in the thickness.

A ratio (Zh/Zl) of an acoustic impedance (Zh) of each high acoustic impedance layer to an acoustic impedance (Zl) of each low acoustic impedance layer may be 4.82 or more. Thereby, the resonance bandwidth can be more effectively broadened.

Each high acoustic impedance layer may be made of silicon dioxide and each low acoustic impedance layer may be made of tungsten.

### Example of a filter Comprising Acoustic Mirror Type Thin Film Bulk Acoustic Resonators

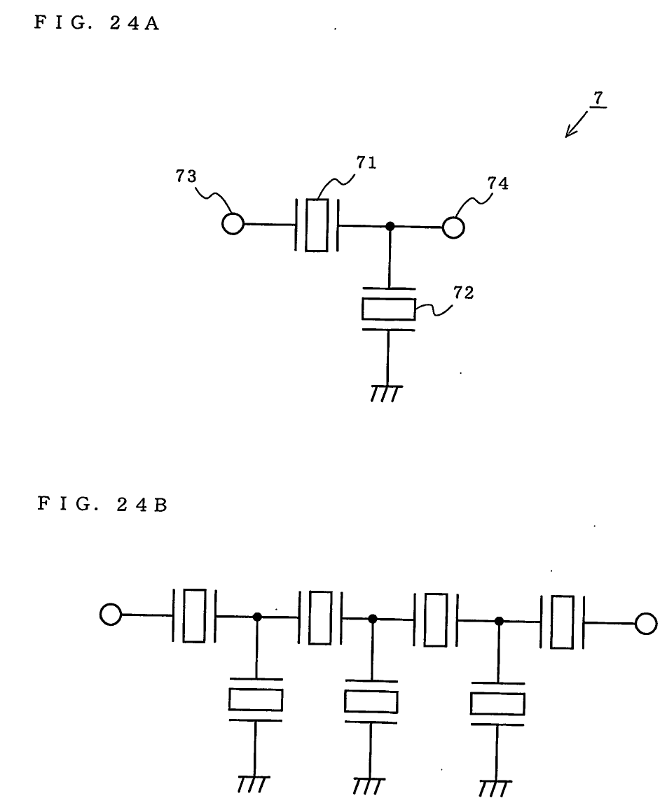

FIGS. 24A and 24B are diagrams showing exemplary filters comprising acoustic mirror type thin film bulk acoustic resonators of the present invention. A one-pole filter 7 of FIG. 24A comprises acoustic mirror type thin film bulk acoustic resonators of any of the types of the first to fifth embodiments of the present invention, the resonators being connected in a L-shape. The first acoustic mirror type thin film bulk acoustic resonator 71 is connected to operate as a series resonator. Specifically, the first acoustic mirror type thin film bulk acoustic resonator 71 is connected in series between an input terminal 73 and an output terminal 74. A second acoustic mirror type thin film bulk acoustic resonator 72 is connected to operate as a parallel resonator. Specifically, the second acoustic mirror type thin film bulk acoustic resonator 72 is connected between a path from the input terminal 73 to the output terminal 74, and a ground surface. Here, if a resonant frequency of the first acoustic mirror type thin film bulk acoustic resonator 71 is set to be higher than a resonant frequency of the second acoustic mirror type thin film bulk acoustic resonator 72, a ladder filter having a bandpass property can be obtained. Preferably, by setting the resonant frequency of the first acoustic mirror type thin film bulk acoustic resonator 71 and an antiresonant frequency of the second acoustic mirror type thin film bulk acoustic resonator 72 to be substantially equal or close to each other, a ladder filter having a flatter passband can be obtained.

Although an L-shaped structure ladder filter is described in the above example, the same effect can be obtained in other ladder filters having a T-shaped structure, a π-shaped structure, a lattice structure and the like. The ladder filter may have one pole as in FIG. 24A or a plurality of poles as in FIG. 24B or the like. If at least one of the thin film bulk acoustic resonators has the feature of any of the first to fifith embodiments, a filter having a broadband effect can be obtained.

### First Example of an Apparatus Comprising Acoustic Mirror Type Thin Film Bulk Acoustic Resonators

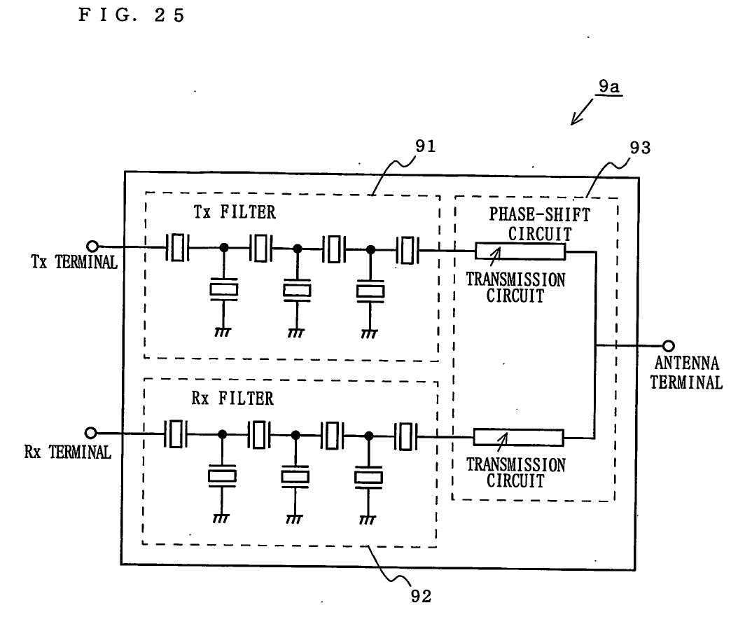

FIG. 25 is a diagram showing a first exemplary apparatus comprising an acoustic mirror type thin film bulk acoustic resonator of the present invention. The apparatus 9a of FIG. 25 is a duplexer comprising the filter of FIG. 24B. The apparatus 9a comprises a Tx filter (transmission filter) 91 including a plurality of acoustic mirror type thin film bulk acoustic resonators, an Rx filter (reception filter) 92 including a plurality of acoustic mirror type thin film bulk acoustic resonators, and a phase-shift circuit 93 including two transmission lines. The Tx filter 91 and the Rx filter 92 are filters which have optimum frequency arrangement, thereby making it possible to obtain a duplexer having excellent properties, such as low loss and the like. Note that the number of filters, the number of acoustic mirror type thin film bulk acoustic resonators included in the filter, and the like can be freely designed, but not are limited to that shown in FIG. 25. Note that at least one of the Tx filter 91 and the Rx filter 92 is a filter which comprises two or more thin film bulk acoustic resonators connected in a ladder form and in which at least one of the thin film bulk acoustic resonators has the feature of any of the first to fifth embodiments.

### Second Example of an Apparatus Comprising Acoustic Mirror Type Thin Film Bulk Acoustic Resonators

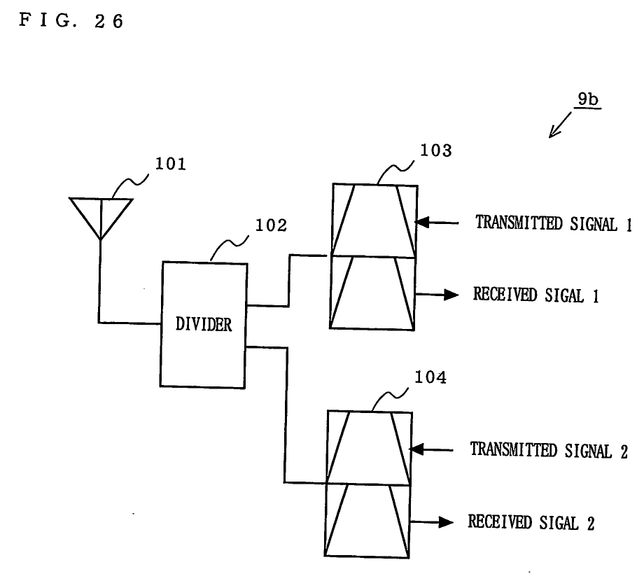

FIG. 26 is a diagram showing a second exemplary apparatus comprising an acoustic mirror type thin film bulk acoustic resonator of the present invention. The apparatus 9b of FIG. 26 is a communication apparatus comprising the duplexer of FIG. 25. The apparatus 9b comprises an antenna 101, a divider 102 for separating two frequency signals, and two duplexers 103 and 104. Either the duplexer 103 or the duplexer 104 is the duplexer of FIG. 25. Thus, by using a duplexer having an excellent property, such as low loss or the like, a low-loss communication apparatus can be achieved.

### Third Example of an Apparatus Comprising Acoustic Mirror Type Thin Film Bulk Acoustic Resonators

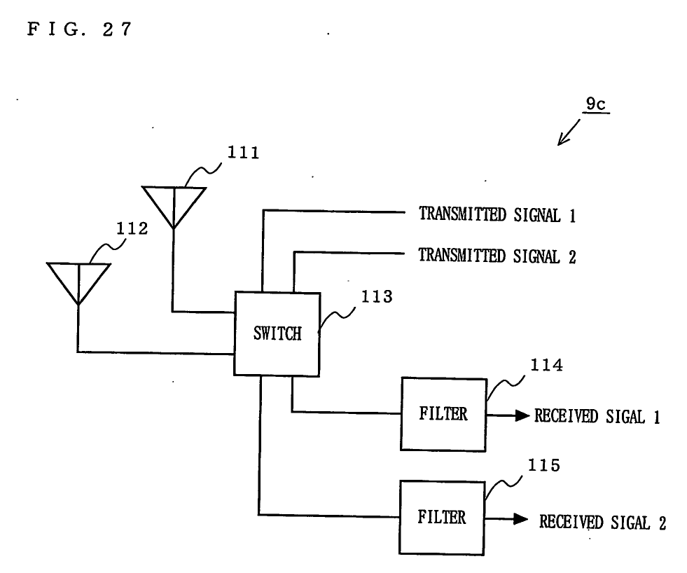

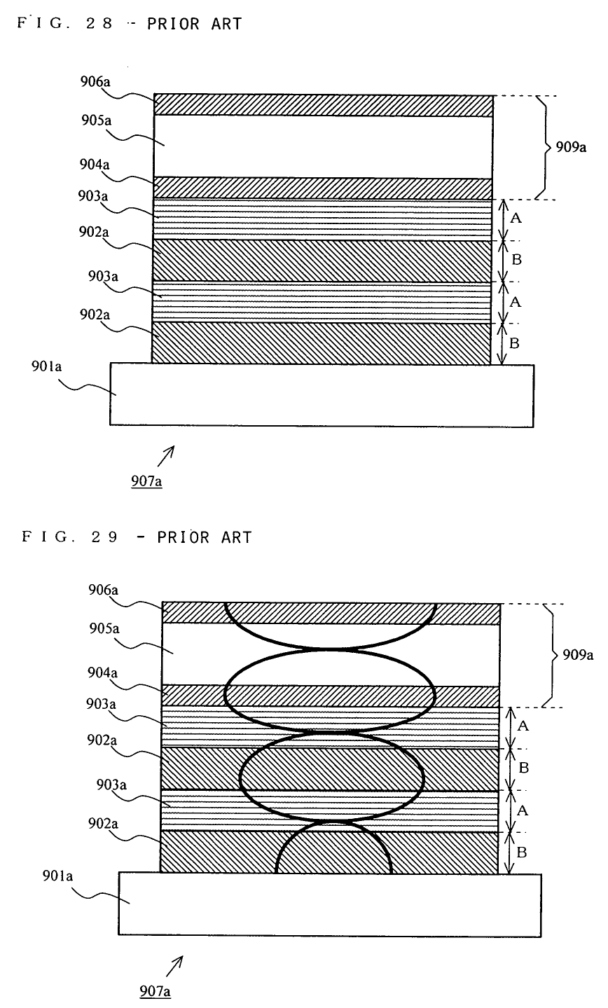

FIG. 27 is a diagram showing a third exemplary apparatus comprising an acoustic resonator of the present invention. The apparatus 9c of FIG. 27 is a communication apparatus comprising the filter of FIG. 24A or 24B. The apparatus 9c comprises two antennas 111 and 112, a switch 113 for switching two frequency signals, and two filters 114 and 115. The communication apparatus of FIG. 27 is different from the communication apparatus of FIG. 26 in that the switch 113 is used instead of the divider 102, and the filters 114 and 115 are used instead of the duplexers 103 and 104. Also with this structure, a low-loss communication apparatus can be obtained. The communication apparatus of the present invention is not limited to those of FIGS. 26 and 27 and may be any communication apparatus comprising at least one bulk acoustic resonator of the present invention.

While the invention has been described in detail, the foregoing description is in all aspects illustrative and not restrictive. It is understood that numerous other modifications and variations can be devised without departing from the scope of the invention.

### INDUSTRIAL APPLICABILITY

The acoustic mirror type thin film bulk acoustic resonator of the present invention, and a filter, a duplexer and a communication apparatus each comprising the same, can have abroad resonance bandwidth, thereby preventing a deterioration in resonance characteristics due to variations in thickness of an acoustic mirror layer and being useful for a wireless apparatus and the like.

1. An acoustic mirror type thin film bulk acoustic resonator comprising:
a substrate;
an acoustic mirror layer provided on the substrate, including a plurality of impedance layers alternately having a high acoustic impedance and a low acoustic impedance; and
a piezoelectric thin film vibrator provided on the acoustic mirror layer, including a lower electrode, a piezoelectric thin film and an upper electrode,
wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

2. The thin film bulk acoustic resonator according to claim 1, wherein the plurality of impedance layers includes a plurality of low acoustic impedance layers and a plurality of high acoustic impedance layers which are alternately disposed, and
an uppermost one of the low acoustic impedance layers which contacts the lower electrode, has a thickness of one fourth of an acoustic wavelength defined from a resonant frequency in free space of the piezoelectric thin film vibrator.

3. The thin film bulk acoustic resonator according to claim 2, wherein each of the plurality of low acoustic impedance layers has a thickness of one fourth of the acoustic wavelength defined from the resonant frequency in free space of the piezoelectric thin film vibrator.

4. The thin film bulk acoustic resonator according to claim 1, wherein the plurality of impedance layers includes a plurality of low acoustic impedance layers and a plurality of high acoustic impedance layers which are alternately disposed, and
an uppermost one of the low acoustic impedance layers which contacts the lower electrode, has a thickness of less than one fourth of an acoustic wavelength defined from a resonant frequency in free space of the piezoelectric thin film vibrator.

5. The thin film bulk acoustic resonator according to claim 4, wherein each of the plurality of low acoustic impedance layers has a thickness of less than one fourth of the acoustic wavelength defined from the resonant frequency in free space of the piezoelectric thin film vibrator.

6. The thin film bulk acoustic resonator according to claim 1, wherein the plurality of impedance layers includes a plurality of low acoustic impedance layers and a plurality of high acoustic impedance layers which are alternately disposed, and
an uppermost one of the low acoustic impedance layers which contacts the lower electrode, has a thickness of more than one fourth of an acoustic wavelength defined from a resonant frequency in free space of the piezoelectric thin film vibrator.

7. The thin film bulk acoustic resonator according to claim 6, wherein each of the plurality of low acoustic impedance layers has a thickness of more than one fourth of the acoustic wavelength defined from the resonant frequency in free space of the piezoelectric thin film vibrator.

8. The thin film bulk acoustic resonator according to claim 1, wherein the plurality of impedance layers includes a plurality of low acoustic impedance layers and a plurality of high acoustic impedance layers which are alternately disposed, and
at least an uppermost one of the plurality of low acoustic impedance layer, has a thickness different from one fourth of an acoustic wavelength defined from a resonant frequency in free space of the piezoelectric thin film vibrator, and
an uppermost one of the high acoustic impedance layers has a thickness different from one fourth of the acoustic wavelength defined from the resonant frequency in free space of the piezoelectric thin film vibrator.

9. The thin film bulk acoustic resonator according to claim 8, wherein each of the plurality of high acoustic impedance layers has a thickness different from one fourth of the acoustic wavelength defined from the resonant frequency in free space of the piezoelectric thin film vibrator.

10. A filter comprising two or more thin film bulk acoustic resonators which are connected in a ladder form, wherein
at least one of the thin film bulk acoustic resonators comprises:
a substrate;
an acoustic mirror layer provided on the substrate, including a plurality of impedance layers alternately having a high acoustic impedance and a low acoustic impedance; and
a piezoelectric thin film vibrator provided on the acoustic mirror layer, including a lower electrode, a piezoelectric thin film and an upper electrode,
wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

11. A duplexer comprising a transmission filter and a reception filter, wherein
at least one of the transmission filter and the reception filter comprises two or more thin film bulk acoustic resonators which are connected in a ladder form, and
at least one of the thin film bulk acoustic resonators comprises:
a substrate;
an acoustic mirror layer provided on the substrate, including a plurality of impedance layers alternately having a high acoustic impedance and a low acoustic impedance; and
a piezoelectric thin film vibrator provided on the acoustic mirror layer, including a lower electrode, a piezoelectric thin film and an upper electrode,
wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.

12. A communication apparatus comprising at least one thin film bulk acoustic resonator, wherein
the at least one thin film bulk acoustic resonators comprises:
a substrate;
an acoustic mirror layer provided on the substrate, including a plurality of impedance layers alternately having a high acoustic impedance and a low acoustic impedance; and
a piezoelectric thin film vibrator provided on the acoustic mirror layer, including a lower electrode, a piezoelectric thin film and an upper electrode,
wherein the sum of a thickness of the lower electrode and a thickness of the upper electrode is 5% or more and 60% or less of a whole thickness of the piezoelectric thin film vibrator, and the thickness of the lower electrode is larger than the thickness of the upper electrode.
